(19) United States
(12) Patent Application Publication
(10) Pub. No.: US 2025/0234719 A1
(43) Pub. Date: Jul. 17, 2025

(54) PIXEL AND DISPLAY DEVICE COMPRISING THE SAME

(71) Applicant: Samsung Display Co., LTD., Yongin-si (KR)

(72) Inventors: Hyeong Pil KIM, Yongin-si (KR); Hyo Min KO, Yongin-si (KR); Sang Gyun KIM, Yongin-si (KR); Il Ha SONG, Yongin-si (KR); Bo Ra LEE, Yongin-si (KR); Hyeon Mi LEE, Yongin-si (KR)

(73) Assignee: Samsung Display Co., LTD., Yongin-si (KR)

(21) Appl. No.: 18/977,451

(22) Filed: Dec. 11, 2024

(30) Foreign Application Priority Data
Jan. 16, 2024 (KR) 10-2024-0006870

(51) Int. Cl. H10K 59/122; H10K 50/15; H10K 50/16; H10K 50/17; H10K 59/35; H10K 101/30

(52) U.S. Cl. CPC H10K 59/122; H10K 50/156; H10K 50/166; H10K 50/171; H10K 59/35; H10K 2101/30

(57) ABSTRACT

A pixel includes a first sub-pixel, a second sub-pixel, and a third sub-pixel, which are disposed adjacent to each other. Each of the first, second, and third sub-pixels includes a lower electrode, a pixel defining layer disposed on the lower electrode and expose an area of the lower electrode, an upper electrode disposed on the pixel defining layer and face the lower electrode, and a light emitting structure disposed between the lower electrode and the upper electrode. The pixel further includes a bank disposed on the pixel defining layer between the second sub-pixel and the third sub-pixel. The light emitting structure of the second sub-pixel and the light emitting structure of the third sub-pixel are separated from each other by the bank.

### CROSS-REFERENCE TO RELATED APPLICATION(S)

This application claims priority to and benefits of Korean patent application No. 10-2024-0006870 under 35 U.S.C. § 119 (a), filed on Jan. 16, 2024, in the Korean Intellectual Property Office (KIPO), the entire contents of which are incorporated herein by reference.

### BACKGROUND

### 1. Technical Field

The disclosure generally relates to a pixel and a display device comprising the same.

### 2. Description of the Related Art

Recently, as interest in information displays is increased, research and development of display devices have been continuously conducted.

### SUMMARY

Embodiments provide a pixel and a display device comprising the same, which can improve reliability by improving the light emission efficiency of a blue sub-pixel.

In accordance with an embodiment of the disclosure, a pixel may include a first sub-pixel, a second sub-pixel, and a third sub-pixel, which are disposed adjacent to each other. Each of the first, second, and third sub-pixels may include a lower electrode, a pixel defining layer disposed on the lower electrode and expose an area of the lower electrode, an upper electrode disposed on the pixel defining layer and face the lower electrode, and a light emitting structure disposed between the lower electrode and the upper electrode. The pixel may further include a bank disposed on the pixel defining layer between the second sub-pixel and the third sub-pixel. The light emitting structure of the second sub-pixel and the light emitting structure of the third sub-pixel may be separated from each other by the bank.

The first sub-pixel may emit light of a first color, the second sub-pixel may emit light of a second color different from the first color, and the third sub-pixel may emit light of a third color different from the second color. The light of the first color may be red light, the light of the second color may be green light, and the light of the third color may be blue light.

The lower electrode may be a cathode electrode, and the upper electrode may be an anode electrode. The light emitting structure may include a first light emitting component which is located on the lower electrode and emits light, a first intermediate layer disposed on the first light emitting component, and a second light emitting component which is located on the first intermediate layer and emits light. The first light emitting component may include a first electron transport component, a first light emitting layer, and a first hole transport component, which are sequentially stacked on the lower electrode. The second light emitting component may include a second electron transport component, a second light emitting layer, and a second hole transport component, which are sequentially stacked on the first intermediate layer. The first intermediate layer may include a first p-type charge generation layer disposed between the first hole transport component and the second electron transport component and a first n-type charge generation layer disposed between the first p-type charge generation layer and the second electron transport component.

The light emitting structure of each of the first and second sub-pixels may further include a first injection layer disposed between the lower electrode of the first and second sub-pixels and the first light emitting component and a second injection layer disposed between the second light emitting component and the upper electrode. The light emitting structure of the third sub-pixel may further include a third injection layer disposed between the lower electrode of the third sub-pixel and the first light emitting component and a fourth injection layer disposed between the second light emitting component and the upper electrode. The first injection layer and the third injection layer may include an electron injection layer. The second injection layer and the fourth injection layer may include a hole injection layer.

Each of the first and third injection layers may include an n-type dopant having a work function in a range of about-4.0 eV to about-1.0 eV. Each of the second and fourth injection layers may include a p-type dopant having a Highest Occupied Molecular Orbital (HOMO) in a range of about-9.5 eV to about-1.5 eV.

The p-type dopant may include at least one of WOₓ, MoOₓ, and VOₓ, and NDP-9, and x may be a rational number between 0 and 3.

The p-type dopant of the second injection layer and the p-type dopant of the fourth injection layer may include different materials. The p-type dopant of the second injection layer may include NDP-9. The p-type dopant of the fourth injection layer may include at least one of an inorganic compound made of a post transition metal and a metalloid, an inorganic compound made of a transition metal and halogen, a post transition metal, and a metalloid.

The first p-type charge generation layer of each of the first and second sub-pixels and the first p-type charge generation layer of the third sub-pixel may include different materials. The first p-type charge generation layer of each of the first and second sub-pixels may include an NDP-9 p-type dopant. The first p-type charge generation layer of the third sub-pixel may include a p-type dopant made of at least one material among an inorganic compound made of a post transition metal and a metalloid, an inorganic compound made of a transition metal and halogen, a post transition metal, and a metalloid.

The post transition metal may include at least one of aluminum (Al), gallium (Ga), indium (In), thallium (Tl), tin (Sn), lead (Pb), flerovium (Fl), bismuth (Bi), and polonium (Po). The metalloid may include at least one of boron (B), silicon (Si), germanium (Ge), arsenic (As), antimony (Sb), tellurium (Te), and astatine (At).

The inorganic compound made of the post transition metal and the metalloid may include at least one of Bi₂Te₃, BiₓTe_{y}, Sb₂Te₃, In₂Te₃, Ga₂Te₃, Al₂Te₃, Tl₂Te₃, As₂Te₃, GeSbTe, SnTe, PbTe, SiTe, GeTe, FlTe, SiGe, AlInSb, AlGaSb, AlAsSb, GaAs, InSb, AlSb, AlAs, AlₓIn₍₁₋ₓ₎Sb, AlSb, GaSb, and AlInGaAs, and x may be a rational number between 0 and 1.

The first and second light emitting layers of each of the first and second sub-pixels may include a host of a green phosphorescent layer and a green phosphorescent dopant. The first and second light emitting layers of the third sub-pixel may include a blue fluorescent host and a blue fluorescent dopant.

The light emitting structure may further include: a second intermediate layer disposed on the second light emitting component; and a third light emitting component located between the second intermediate layer and the upper electrode, the third light emitting component emitting light. The third light emitting component may include a third electron transport component, a third light emitting layer, and a third hole transport component, which are sequentially stacked between the second intermediate layer and the upper electrode. The second intermediate layer may include a second p-type charge generation layer disposed between the second hole transport component and the third electron transport component and a second n-type charge generation layer disposed between the second p-type charge generation layer and the third electron transport component.

The second p-type charge generation layer of each of the first and second sub-pixels and the first p-type charge generation layer of each of the first and second sub-pixels may include a same material. The second p-type charge generation layer of the third sub-pixel and the first p-type charge generation layer of the third sub-pixel may include a same material.

The first and second p-type charge generation layers of each of the first and second sub-pixels may include an NDP-9 p-type dopant. The first and second p-type charge generation layers of the third sub-pixel may include a p-type dopant made of at least one of an inorganic compound made of a post transition metal and a metalloid, an inorganic compound made of a transition metal and halogen, a post transition metal, and a metalloid.

One of the first to third light emitting layers of each of the first and second sub-pixels and one of the first to third light emitting layers of the third sub-pixel may include a same material.

The second light emitting layer of each of the first and second sub-pixels and the second light emitting layer of the third sub-pixel may include a blue fluorescent host and a blue fluorescent dopant. The second p-type charge generation layer of the first sub-pixel, the second p-type charge generation layer of the second sub-pixel, and the second p-type charge generation layer of the third sub-pixel may include a same material.

The second p-type charge generation layer of each of the first to third sub-pixels may include a p-type dopant made of at least one of an inorganic compound made of a post transition metal and a metalloid, an inorganic compound made of a transition metal and halogen, a post transition metal, and a metalloid.

In accordance with an embodiment of the disclosure, a pixel may include a first sub-pixel, a second sub-pixel, and a third sub-pixel, which are disposed adjacent to each other. Each of the first, second, and third sub-pixels may include a cathode electrode, a pixel defining layer disposed on the cathode electrode and expose an area of the cathode electrode, an anode electrode disposed on the pixel defining layer and face the cathode electrode, and a light emitting structure disposed between the cathode electrode and the anode electrode. The pixel may further include a bank disposed on the pixel defining layer between the second sub-pixel and the third sub-pixel. The light emitting structure may include a first light emitting component which is located on the cathode electrode and emits light, a first intermediate layer disposed on the first light emitting component, a second light emitting component which is located on the first intermediate layer and emits light, a second intermediate layer disposed on the second light emitting component, and a third light emitting component which is located between the second intermediate layer and the anode electrode and emits light. The first light emitting component may include a first electron transport component, a first light emitting layer, and a first hole transport component, which are sequentially stacked on the cathode electrode. The second light emitting component may include a second electron transport component, a second light emitting layer, and a second hole transport component, which are sequentially stacked on the first intermediate layer. The third light emitting component may include a third electron transport component, a third light emitting layer, and a third hole transport component, which are sequentially stacked on the second intermediate layer. The first intermediate layer may include a first p-type charge generation layer disposed between the first hole transport component and the second electron transport component and a first n-type charge generation layer disposed between the first p-type charge generation layer and the second electron transport component. The second intermediate layer may include a second p-type charge generation layer disposed between the second hole transport component and the third electron transport component and a second n-type charge generation layer disposed between the second p-type charge generation layer and the third electron transport component. The second light emitting layer of each of the first and second sub-pixels and the second light emitting layer of the third sub-pixel may include a same material and may be integrally formed. The second p-type charge generation layer of each of the first and second sub-pixels and the second p-type charge generation layer of the third sub-pixel may include a same material and may be integrally formed. The first n-type charge generation layer of each of the first and second sub-pixels and the first n-type charge generation layer of the third sub-pixel may include a same material and may be integrally formed.

In accordance with an embodiment of the disclosure, a display device may include a substrate, and a first sub-pixel, a second sub-pixel, and a third sub-pixel, which are disposed on the substrate. Each of the first, second, and third sub-pixels may include a transistor disposed on the substrate, a lower electrode disposed on the transistor and electrically connected to the transistor, a pixel defining layer disposed on the lower electrode and expose an area of the lower electrode, an upper electrode disposed on the pixel defining layer and face the lower electrode, and a light emitting structure disposed between the lower electrode and the upper electrode, the light emitting structure including a first injection layer disposed on the lower electrode and a second injection layer disposed on the bottom of the upper electrode. The display device may further include a bank disposed on the pixel defining layer between the second sub-pixel and the third sub-pixel. The light emitting structure of the second sub-pixel and the light emitting structure of the third sub-pixel may be separated from each other by the bank. The lower electrode may be a cathode electrode, and the upper electrode may be an anode electrode.

The light emitting structure of the first sub-pixel, the second sub-pixel, and the third sub-pixel may further include a first light emitting component located on the first injection layer, a first intermediate layer disposed on the first light emitting component, a second light emitting component disposed on the first intermediate layer, a second intermediate layer disposed on the second light emitting component, and a third light emitting component disposed on the second intermediate layer. Each of the first to third light emitting components may include an electron transport component, a light emitting layer, and a hole transport component, which are sequentially stacked. Each of the first and second intermediate layers may include a p-type charge generation layer and an n-type charge generation layer disposed on the p-type charge generation layer. The p-type charge generation layer of each of the first and second sub-pixels and the p-type charge generation layer of the third sub-pixel may include different materials.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the disclosure.

FIG. 2 is a schematic block diagram illustrating an embodiment of pixels and a driving component in a display device in accordance with an embodiment of the disclosure.

FIG. 3 is a schematic diagram of an equivalent circuit of a sub-pixel shown in FIG. 1 schematically illustrating an electrical connection relationship of components included in a sub-pixel.

FIG. 4 is a schematic plan view illustrating an embodiment of one of pixels shown in FIG. 1.

FIG. 5 is a schematic cross-sectional view taken along line I-I′ shown in FIG. 4.

FIG. 6 is an enlarged schematic cross-sectional view illustrating a portion of the display device shown in FIG. 5.

FIG. 7 is a schematic cross-sectional view schematically illustrating an embodiment of first to third light emitting elements shown in FIG. 5.

FIGS. 8 and 9 are graphs illustrating a current characteristic according to a material of a p-type charge generation layer.

FIG. 10 is a schematic cross-sectional view schematically illustrating another embodiment of the first to third light emitting elements shown in FIG. 5.

FIGS. 11A, 11B, and 12 are schematic cross-sectional views schematically illustrating still another embodiment of the first to third light emitting elements shown in FIG. 5.

### DETAILED DESCRIPTION OF THE EMBODIMENTS

The disclosure may apply various changes and different shape, therefore only illustrate in details with particular examples. However, the examples do not limit to certain shapes but apply to all the change and equivalent material and replacement. The drawings included are illustrated a fashion where the figures are expanded for the better understanding.

Like numbers refer to like elements throughout. In the drawings, the thickness of certain lines, layers, components, elements or features may be exaggerated for clarity. It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure and items required for those skilled in the art to readily understand the content of the disclosure will be described in detail with reference to the accompanying drawings. In the following description, singular forms in the disclosure are intended to include the plural forms as well, unless the context clearly indicates otherwise.

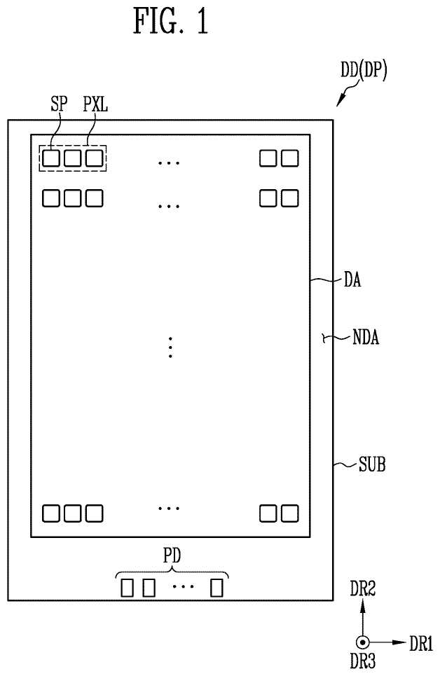

FIG. 1 is a schematic plan view illustrating a display device DD in accordance with an embodiment of the disclosure.

In FIG. 1, for convenience of description, a structure of the display device DD, e.g., a display panel DP provided in the display device DD is schematically illustrated based on a display area DA in which an image is displayed.

Referring to FIG. 1, the display panel DP (or the display device DD) may include the display area DA and a non-display area NDA. The display panel DP may display an image through the display area DA. The non-display area NDA may be disposed at the periphery of the display area DA.

The display panel DP may include a substrate SUB, sub-pixels SP, and pads PD.

The substrate SUB may include a transparent insulating material to transmit light. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

An area on the substrate SUB may be provided as the display area DA such that the sub-pixels SP (or pixels PXL) are disposed therein, and another area on the substrate SUB may be provided as a non-display area NDA. For example, the substrate SUB may include the display area DA including pixel areas in which the respective sub-pixels SP (or the respective pixels PXL) are disposed and the non-display area NDA disposed at the periphery of the display area DA (or adjacent to the display area DA).

The display area DA may have various shapes in a plan view. For example, the display area DA may be provided in various shapes such as a closed polygonal including linear sides, a circle, an ellipse or the like, including a curved side, and a semicircle or the like, including linear and curved sides.

The non-display area NDA may be provided at at least one side of the display area DA. For example, the non-display area NDA may surround a circumference of the display area DA in a plan view.

The sub-pixels SP may be disposed in the display area DA on the substrate SUB. The sub-pixels SP may be arranged in a matrix form in a first direction DR1 and a second direction DR2 intersecting the first direction DR1, but the arrangement form of the sub-pixels SP is not limited thereto. For example, the sub-pixels SP may be arranged in a zigzag form along the first direction DR1 and the second direction DR2. The first direction DR1 may be a row direction, and the second direction DR2 may be a column direction.

Two or more sub-pixels SP among the sub-pixels SP may constitute one pixel PXL.

A component for controlling the sub-pixels SP may be disposed in the non-display area NDA on the substrate SUB. For example, lines electrically connected to the sub-pixels SP may be disposed in the non-display area NDA. The lines may include, for example, gate lines, data lines, and the like.

A driving component electrically connected to the sub-pixels SP to drive the sub-pixels SP may be disposed (or integrated) in the non-display area NDA of the display panel DP. The pads PD may be disposed in the non-display area NDA on the substrate SUB. The pads PD may be electrically connected to the sub-pixels SP through the lines. For example, the pads PD may be electrically connected to the sub-pixels SP through the data lines.

In embodiments, a circuit board (not illustrated) may be electrically connected to the pads PD, using a conductive adhesive member such as an anisotropic conductive film. The circuit board may be a flexible circuit board or a flexible film, which has a flexible material. The driving component may be mounted on the circuit board and electrically connected to the pads PD.

In embodiments, the display panel DP may have a flat display surface. In another embodiment, the display panel DP may at least partially have a round display surface. In embodiments, the display panel DP may be bendable, foldable or rollable. The display panel DP and/or the substrate SUB may include materials having flexibility.

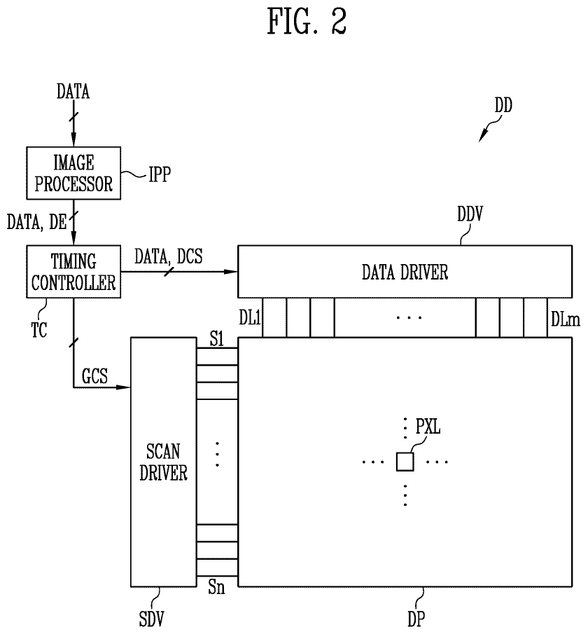

FIG. 2 is a schematic block diagram illustrating an embodiment of pixels PXL and a driving component in a display device DD in accordance with an embodiment of the disclosure.

Referring to FIGS. 1 and 2, the display device DD in accordance with an embodiment of the disclosure may include a display panel DP, a driving component, and a line component.

The display panel DP may display an image, corresponding to a data signal DATA and a scan signal, which are supplied from a data driver DDV and a scan driver SDV. The display panel DP may include multiple pixels PXL for displaying the image.

The driving component may include an image processor IPP, a timing controller TC, the data driver DDV, and the scan driver SDV.

The image processor IPP may output a data enable signal DE and the like together with a data signal DATA supplied from the outside. The image processor IPP may output at least one of a vertical synchronization signal, a horizontal synchronization signal, and a clock signal, in addition to the data enable signal DE.

The timing controller TC may be supplied with the data enable signal DE or a driving signal including the vertical synchronization signal, the horizontal synchronization signal, the clock signal, and the like, and the data signal DATA from the image processor IPP. The timing controller TC may output a gate control signal GCS for controlling an operation timing of the scan driver SDV and a data control signal DCS for controlling an operation timing of the data driver DDV, based on the driving signal.

The data driver DDV may convert a data signal DATA supplied from the timing controller TC into a corresponding data voltage and output the data voltage in response to the data control signal DCS supplied from the timing controller TC. The data driver DDV may supply the data voltage to data lines DL1 to DLm. The data voltage supplied to the data lines DL1 to DLm may be supplied to pixels PXL selected by a scan signal.

The scan driver SDV may apply a scan signal to scan lines SI to Sn in response to the gate control signal GCS supplied from the timing controller TC. For example, in case that the scan driver SDV sequentially supplies the scan signal to the scan lines SI to Sn, the pixels PXL may be sequentially selected in units of horizontal lines.

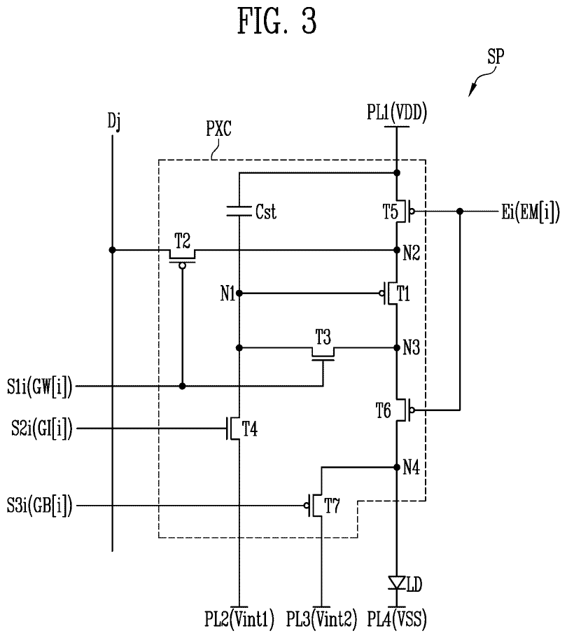

FIG. 3 is a schematic diagram of an equivalent circuit of the sub-pixel SP shown in FIG. 1 schematically illustrating an electrical connection relationship of components included in the sub-pixel SP. For convenience of description, a sub-pixel SP which is located on an ith horizontal line (or ith pixel row) and is connected to a jth data line Dj will be illustrated in FIG. 3.

Referring to FIGS. 1 to 3, the sub-pixel SP may be disposed on the ith horizontal line (or ith pixel row). The sub-pixel SP may include a pixel circuit PXC and a light emitting element LD. The pixel circuit PXC may include first, second, third, fourth, fifth, sixth, and seventh transistors T1, T2, T3, T4, T5, T6, and T7 and a storage capacitor Cst.

A first electrode of the light emitting element LD may be electrically connected to a fourth node N4, and a second electrode of the light emitting element LD may be electrically connected to a fourth power line PL4. The light emitting element LD may generate light with a luminance, corresponding to an amount of current (or driving current) supplied from the first transistor T1. In embodiments, the light emitting element LD may be an organic light emitting diode including an organic light emitting layer.

The first transistor T1 (or driving transistor) may be electrically connected between a first power line PL1 and the first electrode of the light emitting element LD. The first transistor T1 may include a gate electrode electrically connected to a first node N1. The first transistor T1 may control an amount of current (or driving current) flowing from the first power line PL1 to the fourth power line PL4 via the light emitting element LD, based on a voltage of the first node N1. A first power voltage VDD may be applied to the first power line PL1, and a second power voltage VSS may be applied to the fourth power line PL4. The first power voltage VDD may be set as a voltage higher than the second power voltage VSS.

The second transistor T2 may be electrically connected between the jth data line Dj and a second node N2. A gate electrode of the second transistor T2 may be connected to a 1ith scan line S1i (or first scan line). The second transistor T2 may be turned on in case that a first scan signal GW[i] (e.g., the first scan signal GW[i] having a low level) is supplied to the 1ith scan line S1i, to electrically connect the jth data line Dj and the second node N2 to each other. In case that each of the first transistor T1 and the third transistor T3 is in a turn-on state, the second transistor T2 may transfer a data signal of the jth data line Dj to the second node N2 in response to the first scan signal GW[i].

The third transistor T3 may be electrically connected between the first node N1 and a third node N3. A gate electrode of the third transistor T3 may be electrically connected to the 1ith scan line S1i. The third transistor T3 may be turned on in case that the first scan signal GW[i] is supplied to the 1ith scan line S1i. In case that the third transistor T3 is turned on, the first transistor T1 may be connected in a diode form.

The fourth transistor T4 may be electrically connected between the first node N1 and a second power line PL2. A gate electrode of the fourth transistor T4 may be electrically connected to a 2ith scan line S2i (or second scan line). A first initialization power voltage Vint1 may be applied to the second power line PL2. The fourth transistor T4 may be turned on by a second scan signal GI[i] supplied to the 2ith scan line S2i. In case that the fourth transistor T4 is turned on, the first initialization power voltage Vint1 may be supplied to the first node N1 (i.e., the gate electrode of the first transistor T1).

The fifth transistor T5 may be electrically connected between the first power line PL1 and the second node N2. A gate electrode of the fifth transistor T5 may be electrically connected to an ith emission control line Ei (or emission control line). The sixth transistor T6 may be electrically connected between the third node N3 and the light emitting element LD (or the fourth node N4). A gate electrode of the sixth transistor T6 may be electrically connected to the ith emission control line Ei. The fifth transistor T5 and the sixth transistor T6 may be turned off in case that an emission control signal EM[i] (e.g., the emission control signal EM[i] having a high level) is supplied to the ith emission control line Ei, and be turned on in other cases.

The seventh transistor T7 may be electrically connected between the first electrode of the light emitting element LD (i.e., the fourth node N4) and a third power line PL3. A gate electrode of the seventh transistor T7 may be electrically connected to a 3ith scan line S3i. A second initialization power voltage Vint2 may be applied to the third power line PL3. In some embodiments, the second initialization power voltage Vint2 and the first initialization power voltage Vint1 may be same or different from each other. The seventh transistor T7 may be turned on by a third scan signal GB [i] supplied to the 3ith scan line S3i, to supply the second initialization power voltage Vint2 to the first electrode of the light emitting element LD.

The storage capacitor Cst may be connected or formed between the first power line PL1 and the first node N1.

In embodiments, the pixel circuit PXC may include P-type and N-type transistors. Each of the third transistor T3 and the fourth transistor T4 may be formed as an oxide semiconductor transistor including an oxide semiconductor. For example, each of the third transistor T3 and the fourth transistor T4 may be an N-type oxide semiconductor transistor, and include an oxide semiconductor layer as an active layer. However, the disclosure is not limited thereto. The oxide semiconductor transistor may be formed through a low temperature process, and have a charge mobility lower than a charge mobility of the poly-silicon semiconductor transistor. For example, the oxide semiconductor transistor may have an excellent off-current characteristic. Thus, leakage current in the third transistor T3 and the fourth transistor T4 may be minimized.

Other transistors (e.g., the first, second, fifth, sixth, and seventh transistors T1, T2, T5, T6, and T7) may be formed with a poly-silicon semiconductor transistor including a silicon semiconductor, and include a poly-silicon semiconductor layer as an active layer. For example, the active layer may be formed through a low temperature poly-silicon (LTPS) process. For example, the poly-silicon transistor may be a P-type poly-silicon transistor. Because the poly-silicon semiconductor transistor has an advantage of high response speed, the poly-silicon semiconductor transistor may be applied to a switching element which requires fast switching.

As described above, in case that each of the third and fourth transistors T3 and T4 is configured as an oxide semiconductor transistor, the light emitting element LD may be implemented as an inverted light emitting element in some embodiments. This is for the purpose of preventing influence which dispersion according to degradation of the light emitting element LD has on the oxide semiconductor transistor in case that the light emitting element LD is implemented in a normal structure (i.e., a structure in which a lower electrode is an anode and an upper electrode is a cathode electrode).

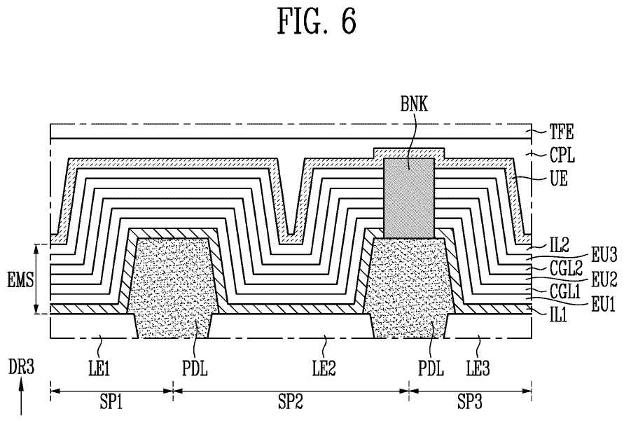

An inverted light emitting element will be described in detail with reference to FIG. 6.

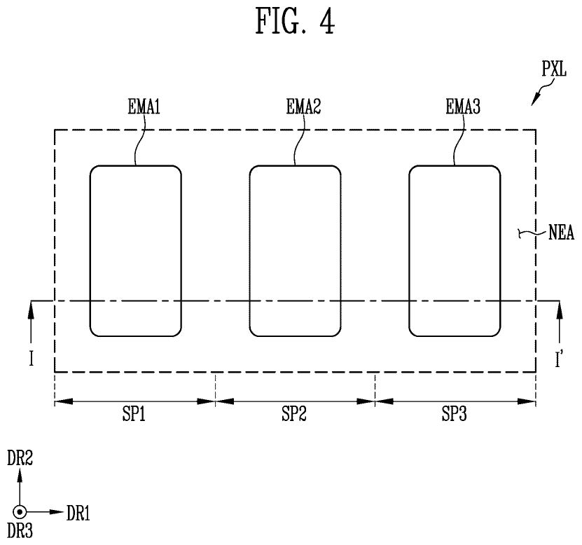

FIG. 4 is a schematic plan view illustrating an embodiment of one of the pixels PXL shown in FIG. 1.

Referring to FIGS. 1 to 4, the pixel PXL1 may include a first sub-pixel SP1, a second sub-pixel SP2, and a third sub-pixel SP3, which are arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

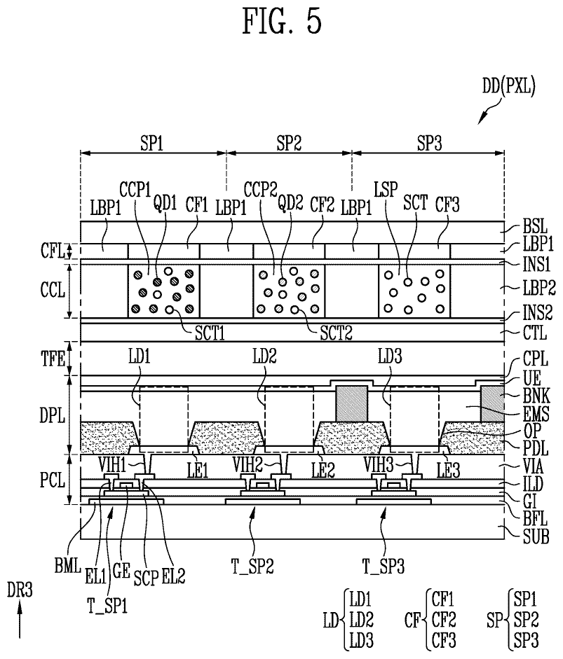

The first emission area EMA1 may be an area in which light is emitted from a portion of a light emitting structure EMS (see FIG. 5), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3.

The first sub-pixel SP1, the second sub-pixel SP2, and the third sub-pixel SP3 may substantially have the same area in a plan view, but the disclosure is not limited thereto. In some embodiments, the second sub-pixel SP2 may have an area greater than an area of the first sub-pixel SP1, and the third sub-pixel SP3 may have an area greater than the area of the second sub-pixel SP2.

The first sub-pixel SP1, the second sub-pixel SP2, and the third sub-pixel SP3 may have a polygonal shape in a plan view. For example, the first sub-pixel SP1, the second sub-pixel SP2, and the third sub-pixel SP3 may have a quadrangular shape or a hexagonal shape, but the disclosure is not limited thereto. In some embodiments, the first sub-pixel SP1, the second sub-pixel SP2, and the third sub-pixel SP3 may have a circular shape, a semi-elliptical shape, or the like.

The arrangement of the sub-pixels is not limited thereto the embodiment illustrated in FIG. 4. Each pixel may include two or more sub-pixels, and the sub-pixels may be arranged in various manners. Each of the sub-pixels may have various shapes, and each of emission areas of the sub-pixels may have various shapes in a plan view.

FIG. 5 is a schematic cross-sectional view taken along line I-I′ shown in FIG. 4.

In FIG. 5, for convenience of description, a cross-sectional structure (or stacked structure) of the display device DD is schematically illustrated based on the pixel PXL formed on the substrate SUB, and a thickness direction of the substrate SUB is indicated as a third direction DR3.

Referring to FIGS. 1 to 5, the display device DD may include at least one pixel PXL disposed in the display area DA of the substrate SUB. The pixel PXL may be provided in a pixel area of the display area DA.

The pixel PXL may include at least one sub-pixel SP. For example, the pixel PXL may include a first sub-pixel SP1, a second sub-pixel SP2, and a third sub-pixel SP3. In embodiments, the first sub-pixel SP1 may be a red sub-pixel, the second sub-pixel SP2 may be a green sub-pixel, and the third sub-pixel SP3 may be a blue sub-pixel. Hereinafter, in case that the first sub-pixel SP1, the second sub-pixel SP2, and the third sub-pixel SP3 are inclusively designated, the first sub-pixel SP1, the second sub-pixel SP2, and the third sub-pixel SP3 may be referred as a sub-pixel SP and/or sub-pixels SP.

Each of the first, second, and third sub-pixels SP1, SP2, and SP3 may include the substrate SUB, a pixel circuit layer PCL, a display element layer DPL, and an encapsulation layer TFE.

The substrate SUB may include a transparent insulating material to transmit light. The substrate SUB may be a rigid substrate or a flexible substrate.

The pixel circuit layer PCL and the display element layer DPL may be disposed on a surface of the substrate SUB to overlap each other in the third direction DR3.

At least one insulating layer may be disposed in the pixel circuit layer PCL. For example, the insulating layer may include a buffer layer BFL, a gate insulating layer GI, an interlayer insulating layer ILD, and a via layer VIA, which are sequentially stacked on the substrate SUB in the third direction DR3. The insulating layer disposed in the pixel circuit layer PCL is not limited to the above-described embodiment, and another insulating layer may be added.

The buffer layer BFL may be entirely disposed on the substrate SUB. The buffer layer BFL may prevent an impurity from being diffused into circuit elements (e.g., transistors) constituting a pixel circuit PXC. The buffer layer BFL may be an inorganic insulating layer including an inorganic material. The buffer layer BFL may include at least one of silicon nitride (SiNₓ), silicon oxide (SiOₓ), silicon oxynitride (SiOₓN_{y}), and aluminum oxide (AlOₓ). The buffer layer BFL may be provided as a single layer or a multi-layer including at least two layers. In case that the buffer layer BFL is provided as the multi-layer, the layers may be formed of a same material or different materials. The buffer layer BFL may be omitted according to a material of the substrate SUB, a process condition, and the like.

The gate insulating layer GI may be entirely disposed on the buffer layer BFL.

The gate insulating layer GI may include the same material as the above-described buffer layer BFL, or include a material appropriate (or selected) from the materials exemplified as the material constituting the buffer layer BFL. For example, the gate insulating layer GI may be an inorganic insulting layer including an inorganic material.

The interlayer insulating layer ILD may be entirely provided and/or formed on the gate insulating layer GI. The interlayer insulating layer ILD may include the same material as the buffer layer BFL, or include a material appropriate (or selected) from the materials exemplified as the material constituting the buffer layer BFL.

The via layer VIA may be entirely provided and/or formed on the interlayer insulating layer ILD. The via layer VIA may be an inorganic insulating layer including an inorganic material or an organic insulating layer including an organic material. The inorganic insulating layer of the via layer VIA may include, for example, at least one of silicon oxide (SiOₓ), silicon nitride (SiNₓ), silicon oxynitride (SiOₓN_{y}), and aluminum oxide (AlOₓ). The organic insulating layer of the via layer VIA may include, for example, at least one of an acrylic resin, an epoxy resin, a phenolic resin, a polyamide resin, a polyimide resin, an unsaturated polyester resin, a poly-phenylene ether resin, a poly-phenylene sulfide resin, and a benzocyclobutene resin. In an embodiment, the via layer VIA may be an organic insulating layer including an organic material.

The via layer VIA may be partially opened to include a via hole. The via hole may be a connection point for electrically connecting a pixel circuit PXC of each sub-pixel SP and a light emitting element LD to each other.

Circuit elements of each of the first to third sub-pixels SP1 to SP3 may be disposed in the pixel circuit layer PCL. For example, a transistor T_SP1 of the first sub-pixel SP1, a transistor T_SP2 of the second sub-pixel SP2, and a transistor T_SP3 of the third sub-pixel SP3 may be disposed in the pixel circuit layer PCL. The transistor T_SP1 of the first sub-pixel SP1 may be one of transistors included in a pixel circuit PXC of the first sub-pixel SP1, the transistor T_SP2 of the second sub-pixel SP2 may be one of transistors included in a pixel circuit PXC of the second sub-pixel SP2, and the transistor T_SP3 of the third sub-pixel SP3 may be one of transistors included in a pixel circuit PXC of the third sub-pixel SP3. In FIG. 5, for clear and brief description, one of transistors of each sub-pixel SP is illustrated, and other circuit elements are omitted.

The transistor T_SP1 of the first sub-pixel SP1 may include a semiconductor layer SCP, a gate electrode GE, a first terminal EL1, and a second terminal EL2.

The gate electrode GE may be disposed on the gate insulating layer GI and covered by the interlayer insulating layer ILD. For example, the gate electrode GE may be a gate conductive layer located between the gate insulating layer GI and the interlayer insulating layer ILD. The gate electrode GE may overlap a portion of the semiconductor layer SCP in the third direction DR3. For example, the gate electrode GE may overlap an active layer of the semiconductor layer SCP in the third direction DR3.

The semiconductor layer SCP may be provided and/or formed on the buffer layer BFL. The semiconductor layer SCP may be a semiconductor layer made of poly-silicon, amorphous silicon, an oxide semiconductor, or the like. The semiconductor layer SCP may include an active layer, a first contact region, and a second contact region. The active layer, the first contact region, and the second contact region may be configured with a semiconductor layer undoped or doped with an impurity. For example, the first contact region and the second contact region may be configured with a semiconductor layer doped with an impurity, and the active layer may be configured with a semiconductor layer undoped with an impurity.

The active layer of the semiconductor layer SCP may overlap the gate electrode GE in the third direction DR3, and may be a channel region. The first contact region of the semiconductor layer SCP may be in contact with an end of the active layer. Also, the first contact region may be electrically connected to the first terminal EL1. The second contact region of the semiconductor layer SCP may be in contact with another end of the active layer. Also, the second contact region may be electrically connected to the second terminal EL2.

The first terminal EL1 may be provided and/or formed on the interlayer insulating layer ILD. For example, the first terminal EL1 may be configured as a source-drain conductive layer formed between the interlayer insulating layer ILD and the via layer VIA. The first terminal EL1 may be in contact with the first contact region of the semiconductor layer SCP through a contact hole penetrating the gate insulating layer GI and the interlayer insulating layer ILD.

The second terminal EL2 may be provided and/or formed on the interlayer insulating layer ILD, and spaced apart from the first terminal EL1. The second terminal EL2 may be configured as a source-drain conductive layer formed between the interlayer insulating layer ILD and the via layer VIA. The second terminal EL2 may be in contact with the second contact region of the semiconductor layer SCP through another contact hole penetrating the gate insulating layer GI and the interlayer insulating layer ILD.

A bottom metal layer BML may be disposed under the transistor T_SP1 of the above-described first sub-pixel SP1.

The bottom metal layer BML may be a first conductive layer located between the substrate SUB and the buffer layer BFL. Although not directly illustrated in the drawing, the bottom metal layer BML may be electrically connected to the transistor T_SP1 of the first sub-pixel SP1, to extend the driving range of a voltage supplied to the gate electrode GE.

As the gate electrode GE, the first terminal EL1, and the second terminal LE2 are electrically connected to other circuit elements and/or lines, the transistor T_SP1 of the first sub-pixel SP1 may be provided as one of the transistors constituting the pixel circuit PXC of the first sub-pixel SP1.

Each of the transistor T_SP2 of the second sub-pixel SP2 and the transistor T_SP3 of the third sub-pixel SP3 may be configured substantially identical to the transistor T_SP1 of the first sub-pixel SP1.

As described above, the pixel circuit layer PCL may include circuit elements of each of the first to third sub-pixels SP1 to SP3.

The display element layer DPL may be disposed on the pixel circuit layer PCL. The display element layer DPL may include first, second, and third lower electrodes LE1, LE2, and LE3, a pixel defining layer PDL, a light emitting structure EMS, and an upper electrode UE.

On the pixel circuit layer PCL (or the via layer VIA), the first to third lower electrodes LE1 to LE3 may be disposed in the first to third sub-pixels SP1 to SP3, respectively. For example, the first lower electrode LE1 may be disposed on the via layer VIA of the first sub-pixel SP1, the second lower electrode LE2 may be disposed on the via layer VIA of the second sub-pixel SP2, and the third lower electrode LE3 may be disposed on the via layer VIA of the third sub-pixel SP3.

Each of the first to third lower electrodes LE1 to LE3 may be electrically connected to a circuit element disposed in the pixel circuit layer PCL through a via hole penetrating the via layer VIA. For example, the first lower electrode LE1 may be electrically connected to the transistor T_SP1 of the first sub-pixel SP1 through a first via hole VIH1 penetrating the via layer VIA, the second lower electrode LE2 may be electrically connected to the transistor T_SP2 of the second sub-pixel SP2 through a second via hole VIH2 penetrating the via layer VIA, and the third lower electrode LE3 may be electrically connected to the transistor T_SP3 of the third sub-pixel SP3 through a third via layer VIH3 penetrating the via layer VIA.

In embodiments, each of the first lower electrode LE1, the second lower electrode LE2, and the third lower electrode LE3 may be a cathode electrode. Each of the first to third lower electrodes LE1 to LE3 may be electrically connected to a corresponding pixel circuit PXC to be supplied with a driving current. The first to third lower electrodes LE1 to LE3 may include a transparent conductive material such as indium tin oxide (ITO), indium zinc oxide (IZO), zinc oxide (ZnOₓ), indium gallium zinc oxide (IGZO), indium tin zinc oxide (ITZO), and a combination thereof. However, the material of the first to third lower electrodes LE1 to LE3 is not limited thereto.

The pixel defining layer PDL may be located over the first to third lower electrodes LE1 to LE3. The pixel defining layer PDL may include an opening OP exposing each of a portion of the first lower electrode LE1, a portion of the second lower electrode LE2, and a portion of the third lower electrode LE3. The pixel defining layer PDL may be a structure defining (or partitioning) an emission area of each of the first to third sub-pixels SP1 to SP3. For example, the pixel defining layer PDL may define the first emission area EMA1 of the first sub-pixel SP1, the second emission area EMA2 of the second sub-pixel SP2, and the third emission area EMA3 of the third sub-pixel SP3.

The pixel defining layer PDL may be configured as an organic insulating layer including an organic material. The pixel defining layer PDL may include at least one of an acrylic resin, an epoxy resin, a phenolic resin, a polyamide resin, a polyimide resin, and the like. In some embodiments, the pixel defining layer PDL may include a light absorption material or have a light absorber coated thereon, to absorb light introduced from the outside. For example, the pixel defining layer PDL may include a carbon-based black pigment. However, the disclosure is not limited thereto.

The pixel defining layer PDL may protrude in the third direction DR3 from the via layer VIA.

In an embodiment, a bank BNK may be disposed on the pixel defining layer PDL. The bank BNK may be disposed on the pixel defining layer PDL between the second sub-pixel SP2 and the third sub-pixel SP3. In an embodiment, the bank BNK may be disposed on the pixel defining layer PDL between the third sub-pixel SP3 and the first sub-pixel SP1. In embodiments, the bank BNK may be disposed only at the periphery of the third sub-pixel SP3 corresponding to a blue sub-pixel.

The bank BNK and the pixel defining layer PDL may include a same material, but the disclosure is not limited thereto. In some embodiments, the bank BNK may be liquid repellent treated to have liquid repellent properties. Examples of liquid repellent treatment may include treatment using a surface modifier as a liquid repellent treatment agent, treatment caused by various energy lines, treatment caused by chemisorption, treatment caused by graft polymerization on a material surface, and the like.

The light emitting structure EMS may be disposed on the first to third lower electrodes LE1 to LE3 exposed by the openings OP of the pixel defining layer PDL. The light emitting structure EMS may include a light emitting layer configured to generate light, an electron transport component configured to transport electrons, a hole transport component configured to transport holes, and the like. However, the disclosure is not limited thereto.

The light emitting structure EMS may fill the openings OP of the pixel defining layer PDL, and may be disposed on the top of the pixel defining layer PDL. In embodiments, a light emitting structure EMS corresponding to the first sub-pixel SP1 and a light emitting structure EMS corresponding to the second sub-pixel SP2 may be connected to each other, and a portion of a light emitting structure EMS corresponding to the third sub-pixel SP3 may be separated from the light emitting structure EMS corresponding to each of the first and second sub-pixels SP1 and SP2. As the bank BNK having liquid repellent properties is disposed on the pixel defining layer PDL between the second sub-pixel SP2 and the third sub-pixel SP3, the light emitting structure EMS of each of the first and second sub-pixels SP1 and SP2 and the light emitting structure EMS of the third sub-pixel SP3 may be separated. Accordingly, the light emitting structure EMS of the first sub-pixel SP1 and the light emitting structure EMS of the second sub-pixel SP2 may be connected to each other, and the light emitting structure EMS of the third sub-pixel SP3 may not be connected to the light emitting structure EMS of each of the first and second sub-pixels SP1 and SP2 but may be separated from the light emitting structure EMS of each of the first and second sub-pixels SP1 and SP2. However, the disclosure is not limited thereto. In some embodiments, a partial component of the light emitting structure EMS of each of the first and second sub-pixels SP1 and SP2 and a partial component of the third sub-pixel SP3 may be connected to each other. In embodiments, the light emitting structure EMS may be formed through a process such as vacuum deposition or inkjet printing.

The upper electrode UE may be disposed on the light emitting structure EMS. In embodiments, the upper electrode UE may be an anode electrode. The upper electrode UE may be a common layer commonly provided in the first to third sub-pixels SP1 to SP3. The upper electrode UE may be provided in a plate shape throughout the entire display device DA. The upper electrode UE may be commonly connected to a power voltage to inject holes into a partial component (e.g., a hole injection layer) of the light emitting structure disposed on the bottom of the light emitting structure. The upper electrode UE may serve as a full mirror which reflects light emitted from the light emitting structure EMS toward a display surface, but the disclosure is not limited thereto.

The upper electrode UE may include a metal material suitable for reflecting light. For example, the upper electrode UE may include at least one of aluminum, silver, magnesium, platinum, palladium, gold, nickel, neodymium, iridium, chromium, titanium, and alloys thereof. However, the material of the upper electrode UE is not limited to the above-described embodiment.

The first lower electrode LE1 (or first electrode), a portion of the light emitting structure EMS, which overlaps the first lower electrode LE1, and a portion of the upper electrode UE (or second electrode), which overlaps the first lower electrode LE1, may constitute a first light emitting element LD1. The second lower electrode LE2 (or first electrode), a portion of the light emitting structure EMS, which overlaps the second lower electrode LE2, and a portion of the upper electrode UE (or second electrode), which overlaps the second lower electrode LE2, may constitute a second light emitting element LD2. The third lower electrode LE3 (or first electrode), a portion of the light emitting structure EMS, which overlaps the third lower electrode LE3, and a portion of the upper electrode UE (or second electrode), which overlaps the third lower electrode LE3, may constitute a third light emitting element LD3. Each of the first to third light emitting elements LD1 to LD3 may be an organic light emitting element having an inverted structure, which includes one lower electrode (or cathode electrode), a portion of the light emitting structure EMS, which overlaps the lower electrode, and a portion of the upper electrode UE (or anode electrode), which overlaps the lower electrode. In each of the first to third sub-pixels SP1 to SP3, electrons injected from the lower electrode and holes injected from the upper electrode UE may be transported into the light emitting layer of the light emitting structure EMS to form excitons, and light may be generated in case that the excitons are changed from an excited state to a ground state. A luminance of light may be determined according to an amount of current flowing through the light emitting layer. A wavelength range of the generated light may be determined according to a configuration of the light emitting layer.

A capping layer CPL may be disposed over the upper electrode UE. The capping layer CPL may improve external light emission efficiency, using the principle of constructive interference. The capping layer CPL may include an organic material, an inorganic material, or a composite material including an organic material and an inorganic material.

The encapsulation layer TFE may be disposed on the capping layer CPL. The encapsulation layer TFE may cover the display element layer DPL. The encapsulation layer TFE may be configured to prevent oxygen and/or moisture from infiltrating into the display element layer DPL. In embodiments, the encapsulation layer TFE may include a structure in which at least one inorganic layer and at least one organic layer are alternately stacked each other. For example, the inorganic layer of the encapsulation layer TFE may include silicon nitride, silicon oxide, silicon oxynitride (SiOₓN_{y}), or the like. For example, the organic layer of the encapsulation layer TFE may include an organic insulating material such as an acrylic resin, an epoxy resin, a phenolic resin, a polyamide resin, a polyimide resin, an unsaturated polyester resin, a polyphenylene resin, a polyphenylenesulfide resin, or benzocyclobutene (BCB). However, the materials of the organic layer and the inorganic layer of the encapsulation layer TFE are not limited thereto.

The pixel PXL in accordance with embodiment of the disclosure may further include an upper substrate disposed on the encapsulation layer TFE with an intermediate layer CTL interposed between the upper substrate and the encapsulation layer TFE. The upper substrate may be located on the encapsulation layer TFE (or coupled to the encapsulation layer TFE) through an adhesion process or the like.

The intermediate layer CTL may be provided and/or formed on the encapsulation layer TFE. The intermediate layer CTL may include an adhesive material for reinforcing adhesion between the encapsulation layer TFE and the upper substrate. The intermediate layer CTL may include a filler configured with an insulating material having insulative and adhesive properties. In some embodiments, the intermediate layer CTL may be used as a planarization layer for reducing a step difference caused by components located thereunder.

The upper substrate may be located on the intermediate layer CTL. The upper substrate may include a color filter layer CFL and a color conversion layer CCL, which are formed on a surface of a base layer BSL (e.g., a surface facing the encapsulation layer TFE) through a continuous process. The upper substrate may be coupled to the encapsulation layer TFE through the intermediate layer CTL. The upper substrate may include the base layer BSL, the color filter layer CFL, a first insulating layer INS1, the color conversion layer CCL, and a second insulating layer INS2, which are sequentially stacked in the opposite direction of the third direction DR3.

The base layer BSL may be a rigid substrate or a flexible substrate, and the material or property of the base layer BSL is not particularly limited. The base layer BSL and the substrate SUB may be configured with a same material or different materials.

The color filter layer CFL may be provided and/or formed on a surface of the base layer BSL.

The color filter layer CFL may be configured to filter light emitted from the light emitting structure EMS, thereby selectively outputting light of a wavelength range or a color, which corresponds to each sub-pixel. The color filter layer CFL may include color filters CF respectively corresponding to the first to third sub-pixels SP1 to SP3. For example, the color filter layer CFL may include a first color filter CF1 corresponding to the first sub-pixel SP1, a second color filter CF2 corresponding to the second sub-pixel SP2, and a third color filter CF3 corresponding to the third sub-pixel SP3. Each of the first to third color filters CF1 to CF3 may pass light in a wavelength range corresponding to a corresponding sub-pixel. For example, the first color filter CF1 may pass light of a red color, the second color filter CF2 may pass light of a green color, and the third color filter CF3 may pass light of a blue color.

A first light blocking layer LBP1 may be located between adjacent color filters CF.

The first light blocking layer LBP1 may be located on the surface of the base layer BSL to correspond to the pixel defining layer PDL. The first light blocking layer LBP1 may include a light blocking material for preventing a light leakage defect in which light is leaked between each of the first to third emission areas EMA1 to EMA3 and emission areas adjacent thereto. Also, the first light blocking layer LBP1 may prevent color mixture of light respectively emitted from the first to third sub-pixels SP1 to SP3, which are located adjacent to each other.

The first insulating layer INS1 may be provided and/or formed on the color filter layer CFL in the opposite direction of the third direction DR3. The first insulating layer INS may be used as a protective layer which covers the color filter layer CFL, thereby protecting the color filter layer CFL. However, the disclosure is not limited thereto. The first insulating layer INS1 may be an inorganic insulating layer including an inorganic material or an organic insulating layer including an organic material. In some embodiments, the first insulating layer INS1 may be omitted.

The color conversion layer CCL may be provided and/or formed on a surface of the first insulating layer INS1 (e.g., a surface facing the encapsulation layer TFE).

The color conversion layer CCL may include a first color conversion layer CCP1, a second color conversion layer CCP2, a light scattering layer LSP, and a second light blocking layer LBP2.

The first color conversion layer CCP1 may be located on the surface of the first insulating layer INS1 to correspond to the light emitting structure EMS of the first sub-pixel SP1, and include first color conversion particles QD1 for converting light emitted from the light emitting structure EMS into light of a red color. In embodiments, the first color conversion layer CCP1 may include multiple first color conversion particles QD1 dispersed in a matrix material such as base resin. A content of the first color conversion particles QD1 in the first color conversion layer CCP1 may be in a range of about 10% to about 60%, but the disclosure is not limited thereto. In some embodiments, the first color conversion layer CCP1 may include first light scattering particles SCT1 (or scatterers) having a content in a range of about 2% to about 10% in addition to the first color conversion particles QD1. The first color conversion layer CCP1 may have a thickness in a range of about 2 μm to about 18 μm, but the disclosure is not limited thereto.

The second color conversion layer CCP2 may be located on the surface of the first insulating layer INS1 to correspond to the light emitting structure EMS of the second sub-pixel SP2, and include second color conversion particles QD2 for converting light emitted from the light emitting structure EMS into light of a green color having excellent color reproducibility. In embodiments, the second color conversion layer CCP2 may include multiple second color conversion particles QD2 dispersed in a matrix material such as base resin. A content of the second color conversion particles QD2 in the second color conversion layer CCP2 may be in a range of about 10% to about 60%, but the disclosure is not limited thereto. In some embodiments, the second color conversion layer CCP2 may include second light scattering particles SCT2 (or scatterers) having a content in a range of about 2% to about 10% in addition to the second color conversion particles QD2. The second color conversion layer CCP2 may have a thickness in a range of about 2 μm to about 18 μm, but the disclosure is not limited thereto.

In some embodiments, in case that light emitted from the light emitting structure EMS of the second sub-pixel SP2 is light of the green color, the color conversion layer CCL may include a light scattering layer instead of the second color conversion layer CCP2.

The light scattering layer LSP may be located on the surface of the first insulating layer INS1 to correspond to the light emitting structure EMS of the third sub-pixel SP3, and be a transparent layer (or transparent window) which transmits light emitted from the light emitting structure EMS as it is. The light scattering layer LSP may include light scattering particles SCT for scattering light emitted from the light emitting structure EMS in various directions. The light scattering layer LSP may have a thickness in a range of about 1 μm to about 12 μm, but the disclosure is not limited thereto.

The second light blocking layer LBP2 may be disposed on the surface of the first insulating layer INS1 to correspond to the pixel defining layer PDL (or the first light blocking layer LBP1). The second light blocking layer LBP2 may be a structure defining a position at which the first color conversion layer CCP1 is formed, a position at which the second color conversion layer CCP2 is formed, and a position at which the light scattering layer LSP is formed.

The second light blocking layer LBP2 may include at least one light blocking material and/or at least one reflective material, or include the same material as the first light blocking layer LBP1.

The second insulating layer INS2 may be provided and/or formed on a surface of the color conversion layer CCL in the opposite direction of the third direction DR3. In an embodiment, the second insulating layer INS2 may be used as a protective layer which covers the color conversion layer CCL, thereby protecting the color conversion layer CCL, but the disclosure is not limited thereto. The second insulating layer INS2 may be an inorganic insulating layer including an inorganic material or an organic insulating layer including an organic material.

As described above, as the color conversion layer CCL and the color filter layer CFL are disposed on the top of the encapsulation layer TFE, the color conversion layer CCL and the color filter layer CFL may convert light emitted from the light emitting structure EMS of each of the first to third sub-pixels SP1, SP2, and SP3 into light having excellent color reproducibility and emit the converted light, so that the light emission efficiency of each of the first to third sub-pixels SP1, SP2, and SP3 may be further improved.

FIG. 6 is an enlarged schematic cross-sectional view illustrating a portion of the display device shown in FIG. 5.

In FIG. 6, the first to third lower electrodes LE1, LE2, and LE3, the light emitting structure EMS, and the bank BNK are illustrated between the first sub-pixel SP1 and the second sub-pixel SP2 (or in a boundary area) and between the second sub-pixel SP2 and the third sub-pixel SP3 (or in a boundary area). Also, in FIG. 6, for clarity, the pixel defining layer PDL, the capping layer CPL, and the encapsulation layer TFE are further illustrated.

In FIG. 6, portions different from those of the above-described embodiments will be described to avoid redundancy.

Referring to FIGS. 5 and 6, the bank BNK may be disposed on the pixel defining layer PDL located between the second sub-pixel SP2 and the third sub-pixel SP3.

The bank BNK may be liquid repellent treated to have liquid repellent properties. Accordingly, the light emitting structure EMS of the second sub-pixel SP2 and the light emitting structure EMS of the third sub-pixel SP3 may be separated from each other. However, the disclosure is not limited thereto. In some embodiments, a partial component of the light emitting structure EMS of the second sub-pixel SP2 and a partial component of the light emitting structure EMS of the third sub-pixel SP3 may be disposed on the bank BNK and connected to each other.

The light emitting structure EMS of each of the first to third sub-pixels SP1 to SP3 may have a tandem structure in which a first light emitting component EU1, a second light emitting component EU2, and a third light emitting component EU3 are stacked.

In embodiments, the light emitting structure EMS of each of the first to third sub-pixels SP1 to SP3 may include a first injection layer IL1, the first light emitting component EU1, a first intermediate layer CGL1, the second light emitting component EU2, a second intermediate layer CGL2, the third light emitting component EU3, and a second injection layer IL2.

The first injection layer IL1 may be disposed between each of the first to third lower electrodes LE1, LE2, and LE3 (or cathode electrode) and the first light emitting component EU1. The first light emitting component EU1 may be disposed between the first injection layer IL1 and the first intermediate layer CGL1. The first intermediate layer CGL1 may be disposed between the first light emitting component EU1 and the second light emitting component EU2. The second light emitting component EU2 may be disposed between the first intermediate layer CGL1 and the second intermediate layer CGL2. The second intermediate layer CGL2 may be disposed between the second light emitting component EU2 and the third light emitting component EU3. The third light emitting component EU3 may be disposed between the second intermediate layer CGL2 and the second injection layer IL2. The second injection layer IL2 may be disposed between the third light emitting component EU3 and the upper electrode UE (or anode electrode).

Each of the first to third light emitting components EU1, EU2, and EU3 may include an electron transport component, a light emitting component, a hole transport component, which are sequentially stacked in a direction toward the upper electrode UE from a corresponding lower electrode.

Each of the first and second intermediate layers CGL1 and CGL2 may include a first charge generation layer and a second charge generation layer, which are stacked in the third direction DR3. In embodiments, the first charge generation layer may be a p-type charge generation layer, and the second charge generation layer may be an n-type charge generation layer.

The first injection layer IL1 may be an electron injection layer which is located between each of the first to third lower electrodes LE1 to LE3 and an electron transport component of the first light emitting component EU1, and lowers an injection barrier between a corresponding lower electrode and the electron transport component of the first light emitting component EU1. The first injection layer IL1 may include an electron injection material and an n-type dopant.

The second injection layer IL2 may be a hole injection layer which is located between the upper electrode UE and a hole transport component of the third light emitting component EU3, and lowers an injection barrier between the upper electrode UE and the hole transport component of the third light emitting component EU3. The second injection layer IL2 may include a hole injection material and a p-type dopant.

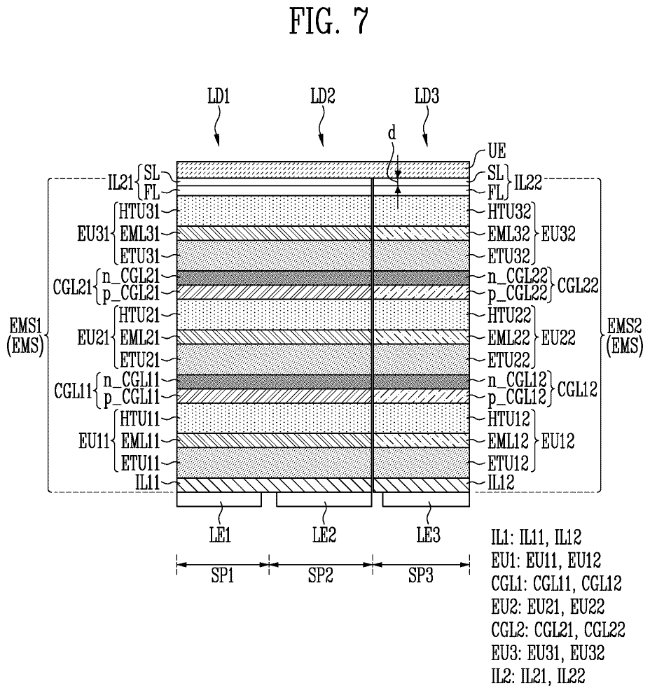

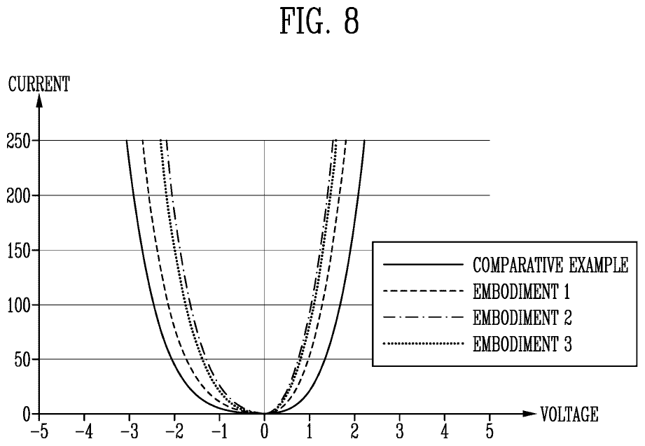

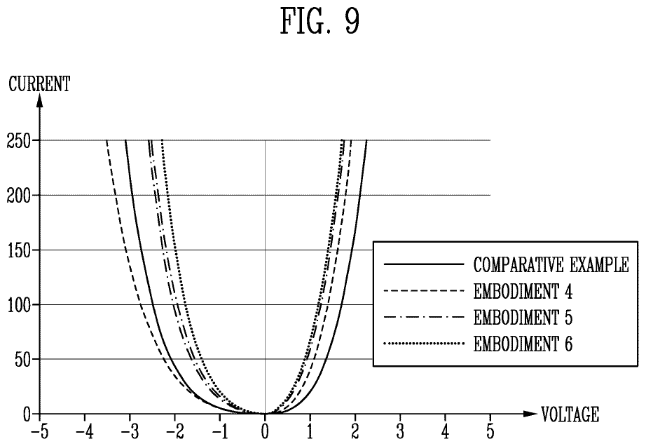

FIG. 7 is a schematic cross-sectional view schematically illustrating an embodiment of the first to third light emitting elements LD1, LD2, and LD3 shown in FIG. 5. FIGS. 8 and 9 are graphs illustrating a current characteristic according to a material of a p-type charge generation layer. In FIG. 7, for convenience of description, a light emitting structure EMS1 of the first and second sub-pixels SP1 and SP2 and a light emitting structure EMS2 of the third sub-pixel SP3 are illustrated separately from each other.

Referring to FIGS. 5 to 9, the first light emitting element LD1 may be located in the first sub-pixel SP1, the second light emitting element LD2 may be located in the second sub-pixel SP2, and the third light emitting element LD3 may be located in the third sub-pixel SP3. In embodiments, each of the first to third light emitting elements LD1, LD2, and LD3 may be an organic light emitting element having an inverted structure, in which a cathode electrode is formed on the top of the pixel circuit layer PCL, and an electron transport component, a light emitting layer, a hole transport component, and an anode electrode are sequentially formed on the top of a cathode electrode.

Each of the first to third light emitting elements LD1 to LD3 may include a lower electrode LE1, LE2, and LE3, a light emitting structure EMS, and an upper electrode UE. Light emitting structures EMS of the first and second sub-pixels SP1 and SP2 may be connected to each other. A light emitting structure EMS of the third sub-pixels SP3 may be separated from the light emitting structure EMS of the first and second sub-pixels SP1 and SP2. Hereinafter, for convenience of description, the light emitting structure EMS of the first and second sub-pixels SP1 and SP2 is designated as a first light emitting structure EMS1, and the light emitting structure EMS of the third sub-pixel SP3 is designated as a second light emitting structure EMS2. In case that the first light emitting structure EMS1 and the second light emitting structure EMS2 are inclusively designated, each of the first light emitting structure EMS1 and the second light emitting structure EMS2 is designated as a light emitting structure EMS.

The light emitting structure EMS may be disposed between the lower electrode and the upper electrode UE. In the first sub-pixel SP1, the first light emitting structure EMS1 may be disposed between a first lower electrode LE1 and the upper electrode UE. In the second sub-pixel SP1, the first light emitting structure EMS1 may be disposed between a second lower electrode LE2 and the upper electrode UE. In the third sub-pixel SP3, the second light emitting structure EMS2 may be disposed between a third lower electrode LE3 and the upper electrode UE. Each of the first, second, and third lower electrodes LE1, LE2, and LE3 may be a cathode electrode, and the upper electrode UE may be an anode electrode.

The light emitting structure EMS may include a first injection layer IL1, a first light emitting component EU1, a first intermediate layer CGL1, a second light emitting component EU2, a second intermediate layer CGL2, a third light emitting component EU3, and a second injection layer IL2.

Each of the first to third light emitting components EU1, EU2, and EU3 may emit light according to an applied current. Each of the first and second intermediate layers CGL1 and CGL2 may provide electrons and/or holes. The first injection layer IL1 may be located between the lower electrode (or cathode electrode) and the first light emitting component EU1, thereby lowering an injection barrier between the lower electrode and an electron transport component of the first light emitting component EU1. The second injection layer IL2 may be located between the third light emitting component EU3 and the upper electrode UE (or anode electrode), thereby lowering an injection barrier between a hole transport component of the third light emitting component EU3 and the upper electrode UE.

The first light emitting structure EMS1 may include an eleventh injection layer IL11, an eleventh light emitting component EU11, an eleventh intermediate layer CGL11, a twenty-first light emitting component EU21, a twenty-first intermediate layer CGL21, a thirty-first light emitting component EU31, and a twenty-first injection layer IL21. The second light emitting structure EMS2 may include a twelfth injection layer IL12, a twelfth light emitting component EU12, a twelfth intermediate layer CGL12, a twenty-second light emitting component EU22, a twenty-second intermediate layer CGL22, a thirty-second light emitting component EU32, and a twenty-second injection layer IL22.

The eleventh injection layer IL11 and the twelfth injection layer IL12 may correspond to the first injection layer IL1, the eleventh light emitting component EU11 and the twelfth light emitting component EU12 may correspond to the first light emitting component EU1, the eleventh intermediate layer CGL11 and the twelfth intermediate layer CGL12 may correspond to the first intermediate layer CGL1, the twenty-first light emitting component EU21 and the twenty-second light emitting component EU22 may correspond to the second light emitting component EU2, the twenty-first intermediate layer CGL21 and the twenty-second intermediate layer CGL 22 may correspond to the second intermediate layer CGL2, the thirty-first light emitting component EU31 and the thirty-second light emitting component EU32 may correspond to the third light emitting component EU3, and the twenty-first injection layer IL21 and the twenty-second injection layer IL22 may correspond to the second injection layer IL2.

The eleventh injection layer IL11 may be disposed between each of the first and second lower electrodes LE1 and LE2 and an eleventh electron transport component ETU11 of the first light emitting component EU11. The twelfth injection layer IL12 may be disposed between the third lower electrode LE3 and a twelfth electron transport component ETU12 of the twelfth light emitting component EU12. The eleventh injection layer IL11 may function to inject electrons injected from each of the first and second lower electrodes LE1 and LE2 (or cathode electrode) in a direction in which an eleventh light emitting layer EML11 of the eleventh light emitting component EU11 is located. The twelfth injection layer IL12 may function to inject electrons injected from the third lower electrode LE3 (or cathode) in a direction in which a twelfth light emitting layer EML12 of the twelfth light emitting component EU12 is located.

The eleventh injection layer IL11 and the twelfth injection layer IL12 may include at least one of an electron injection material and an n-type dopant. The electron injection material may include, for example, a lanthanum group metal such as LiF, LiQ, NaQ, Li₂O, BaO, NaCl, CsF or Yb, a halogenated metal such as RbCl or RbI, the like, or a combination thereof. However, the disclosure is not limited thereto. In embodiments, the eleventh injection layer IL11 and the twelfth injection layer IL12 may include an n-type dopant made of at least one of an electron injection material and a metal having a work function in a range of about-4.0 eV to about-1.0 eV. The metal may include ytterbium (Yb), lithium (Li), and the like, but the disclosure is not limited thereto.

The eleventh injection layer IL11 and the twelfth injection layer IL12 may include a same material. In some embodiments, a metal selected as the n-type dopant of the eleventh injection layer IL11 and a metal selected as the n-type dopant of the twelfth injection layer IL12 may be different from each other. For example, the n-type dopant of the eleventh injection layer IL11 may be ytterbium, and the n-type dopant of the twelfth injection layer IL12 may be lithium. However, the disclosure is not limited thereto. For example, the n-type dopant of the eleventh injection layer IL11 may be lithium, and the n-type dopant of the twelfth injection layer IL12 may be ytterbium.

The eleventh light emitting component EU11 may include the eleventh electron transport component ETU11, the eleventh light emitting layer EML11, and an eleventh hole transport component HTU11. The twelfth light emitting component EU12 may include the twelfth electron transport component ETU12, the twelfth light emitting layer EML12, and a twelfth hole transport component HTU12.

The eleventh electron transport component ETU11 may function to move electrons injected from the eleventh injection layer IL11 to the eleventh light emitting layer EML11 adjacent thereto. The twelfth electron transport component ETU12 may function to move electrons injected from the twelfth injection layer IL12 to the twelfth light emitting layer EML12 adjacent thereto. The eleventh electron transport component ETU11 and the twelfth electron transport component ETU12 may include at least one electron transport material. The electron transport material may include, for example, an oxazole-based compound, an iso-oxazole-based compound, a triazole-based compound, an isothiazole-based compound, an oxadiazole-based compound, a thiadiazole-based compound, a perylene-based compound, a pyrene-based compound, a triazine-based compound, an antracene-based compound, an aluminum complex (e.g., tris(8-quinolinolato)-aluminum (Alq3), BAlq, SAlq or Almq3), a gallium complex (e.g., Gaq′2OPiv, Gaq′2OAc or 2 (Gaq′2)), and the like. However, the disclosure is not limited thereto. In each of the eleventh and twelfth electron transport components ETU11 and EUT12, the above-described the electron transport materials may be used alone or as a mixture of two or more, but the disclosure is not limited thereto. In embodiments, the eleventh electron transport component ETU11 and the twelfth electron transport component ETU12 may include a same material. The eleventh electron transport component ETU11 and the twelfth electron transport component ETU12 may not be separated from each other but may be connected to each other to be commonly provided in the first to third sub-pixels SP1 to SP3. However, the disclosure is not limited thereto. In some embodiments, the eleventh electron transport component ETU11 and the twelfth electron transport component ETU12 may be separated from each other by the bank BNK.

In FIG. 7, it is illustrated that the eleventh electron transport component ETU11 and the twelfth electron transport component ETU12 have a same thickness. However, the disclosure is not limited thereto. In some embodiments, the eleventh electron transport component ETU11 and the twelfth electron transport component ETU12 may have different thicknesses.

The eleventh hole transport component HTU11 may function to move holes injected from an eleventh p-type charge generation layer p_CGL11 of the eleventh intermediate layer CGL11 to the eleventh light emitting layer EML11 adjacent thereto. The twelfth hole transport component HTU12 may function to move holes injected from a twelfth p-type charge generation layer p_CGL12 of the twelfth intermediate layer CGL12 to the twelfth light emitting layer EML12 adjacent thereto. The eleventh hole transport component HTU11 and the twelfth hole transport component HTU12 may include at least one hole transport material. The hole transport material may include, for example, at least one of a carbazole derivative such as N-phenylcarbazole and polyvinylcarbazole, an ordinary amine derivative having an aromatic condensed ring, such as N,N′-bis(3-methylphenyl)-N,N′-diphenyl-[1,1-biphenyl]-4,4′-diamine (TPD) and N,N′-di(naphthalene-1-yl)-N,N′-diphenyl benzidine (-NPD), and a triphenylamine-based material such as TCTA (4,4′,4″-tris(N-carbazolyl)triphenylamine. However, the disclosure is not limited thereto. In embodiments, the eleventh hole transport component HTU11 and the twelfth hole transport component HTU12 may include a same material. The eleventh hole transport component HTU11 and the twelfth hole transport component HTU12 may not be separated from each other but may be connected to each other to be commonly provided in the first to third sub-pixels SP1 to SP3. However, the disclosure is not limited thereto. In some embodiments, the eleventh hole transport component HTU11 and the twelfth hole transport component HTU12 may be separated from each other by the bank BNK.

In FIG. 7, it is illustrated that the eleventh hole transport component HTU11 and the twelfth hole transport component HTU12 have a same thickness. However, the disclosure is not limited thereto. In some embodiments, the eleventh hole transport component HTU11 and the twelfth hole transport component HTU12 may have different thicknesses.

The eleventh light emitting layer EML11 and the twelfth light emitting layer EML12 may include different materials, thereby emitting lights of different colors. For example, the eleventh light emitting layer EML11 may be a green light emitting layer which includes a host of a green phosphorescent layer and a green phosphorescent dopant, thereby emitting green light. The twelfth light emitting layer EML12 may be a blue light emitting layer which includes a blue fluorescent host and a blue fluorescent dopant, thereby emitting blue light.

The twenty-first light emitting component EU21 may include a twenty-first electron transport component ETU21, a twenty-first light emitting layer EML21, and a twenty-first hole transport component HTU21. The twenty-second light emitting component EU22 may include a twenty-second electron transport component ETU22, a twenty-second light emitting layer EML22, and a twenty-second hole transport component HTU22.

The twenty-first electron transport component ETU21 may function to move electrons injected from an eleventh n-type charge generation layer n_CGL11 of the eleventh intermediate layer CGL11 to the twenty-first light emitting layer EML21 adjacent thereto. The twenty-second electron transport component ETU22 may function to move electrons injected from a twelfth n-type charge generation layer n_CGL12 of the twelfth intermediate layer CGL12 to the twenty-second light emitting layer EML22. The twenty-first electron transport component ETU21 and the twenty-second electron transport component ETU22 may include at least one of the above-described electron transport materials. In embodiments, the twenty-first electron transport component ETU21 and the twenty-second electron transport component ETU22 may include a same material. The twenty-first electron transport component ETU21 and the twenty-second electron transport component ETU22 may not be separated from each other but may be connected to each other to be commonly provided in the first to third sub-pixels SP1 to SP3. However, the disclosure is not limited thereto. In some embodiments, the twenty-first electron transport component ETU21 and the twenty-second electron transport component ETU22 may be separated from each other by the bank BNK.

In FIG. 7, it is illustrated that the twenty-first electron transport component ETU21 and the twenty-second electron transport component ETU22 have a same thickness. However, the disclosure is not limited thereto. In some embodiments, the twenty-first electron transport component ETU21 and the twenty-second electron transport component ETU22 may have different thicknesses.

The twenty-first hole transport component HTU21 may function to move holes injected from a twenty-first p-type charge generation layer p_CGL21 of the twenty-first intermediate layer CGL21 to the twenty-first light emitting layer EML21 adjacent thereto. The twenty-second hole transport component HTU22 may function to move holes injected from a twenty-second p-type charge generation layer p_CGL22 of the twenty-second intermediate layer CGL22 to the twenty-second light emitting layer EML22 adjacent thereto. The twenty-first hole transport component HTU21 and the twenty-second hole transport component HTU22 may include at least one of the above-described hole transport materials. In some embodiments, the twenty-first hole transport component HTU21 and the twenty-second hole transport component HTU22 may include a same material. The twenty-first hole transport component HTU21 and the twenty-second hole transport component HTU22 may not be separated from each other but may be connected to each other to be commonly provided in the first to third sub-pixels SP1 to SP3. However, the disclosure is not limited thereto. In some embodiments, the twenty-first hole transport component HTU21 and the twenty-second hole transport component HTU22 may be separated from each other by the bank BNK.

In FIG. 7, it is illustrated that the twenty-first hole transport component HTU21 and the twenty-second hole transport component HTU22 have a same thickness. However, the disclosure is not limited thereto. In some embodiments, the twenty-first hole transport component HTU21 and the twenty-second hole transport component HTU22 may have different thicknesses.

The twenty-first light emitting layer EML21 and the twenty-second light emitting layer EML22 may include different materials, thereby emitting lights of different colors. For example, the twenty-first light emitting layer EML21 may be a green light emitting layer which includes a host of a green phosphorescent layer and a green phosphorescent dopant, thereby emitting green light. The twenty-second light emitting layer EML22 may be a blue light emitting layer which includes a blue fluorescent host and a blue fluorescent dopant, thereby emitting blue light.

The thirty-first light emitting component EU31 may include a thirty-first electron transport component ETU31, a thirty-first light emitting layer EML31, and a thirty-first hole transport component HTU31. The thirty-second light emitting component EU32 may include a thirty-second electron transport component ETU32, a thirty-second light emitting layer EML32, and a thirty-second hole transport component HTU32.

The thirty-first electron transport component ETU31 may function to move electrons injected from a twenty-first charge generation layer n_CGL21 of the twenty-first intermediate layer CGL21 to the thirty-first light emitting layer EML31 adjacent thereto. The thirty-second electron transport component ETU32 may function to move electrons injected from a twenty-second charge generation layer n_CGL22 of the twenty-second intermediate layer CGL22 to the thirty-second light emitting layer EML32 adjacent thereto. The thirty-first electron transport component ETU31 and the thirty-second electron transport component ETU32 may include at least one of the above-described electron transport materials. In embodiments, the thirty-first electron transport component ETU31 and the thirty-second electron transport component ETU32 may include a same material. The thirty-first electron transport component ETU31 and the thirty-second electron transport component ETU32 may not be separated from each other but may be connected to each other to be commonly provided in the first to third sub-pixels SP1 to SP3. However, the disclosure is not limited thereto. In some embodiments, the thirty-first electron transport component ETU31 and the thirty-second electron transport component ETU32 may be separated from each other by the bank BNK.

In FIG. 7, it is illustrated that the thirty-first electron transport component ETU31 and the thirty-second electron transport component ETU32 have a same thickness. However, the disclosure is not limited thereto. In some embodiments, the thirty-first electron transport component ETU31 and the thirty-second electron transport component ETU32 may have different thicknesses.

The thirty-first hole transport component HTU31 may function to move holes injected from the twenty-first injection layer IL21 to the thirty-first light emitting layer EML31 adjacent thereto. The thirty-second hole transport component HTU32 may function to move hole injected from the twenty-second injection layer IL22 to the thirty-second light emitting layer EML32 adjacent thereto. The thirty-first hole transport component HTU31 and the thirty-second hole transport component HTU32 may include at least one of the above-described hole transport materials. In embodiments, the thirty-first hole transport component HTU31 and the thirty-second hole transport component HTU32 may include a same material. The thirty-first hole transport component HTU31 and the thirty-second hole transport component HTU32 may not be separated from each other but may be connected to each other to be commonly provided in the first to third sub-pixels SP1 to SP3. However, the disclosure is not limited thereto. In some embodiments, the thirty-first hole transport component HTU31 and the thirty-second hole transport component HTU32 may be separated from each other by the bank BNK.

In FIG. 7, it is illustrated that the thirty-first hole transport component HTU31 and the thirty-second hole transport component HTU32 have a same thickness. However, the disclosure is not limited thereto. In some embodiments, the thirty-first hole transport component HTU31 and the thirty-second hole transport component HTU32 may have different thicknesses.

The thirty-first light emitting layer EML31 and the thirty-second light emitting layer EML32 may include different materials, thereby emitting lights of different colors. For example, the thirty-first light emitting layer EML31 may be a green light emitting layer which includes a host of a green phosphorescent layer and a green phosphorescent dopant, thereby emitting green light. The thirty-second light emitting layer EML32 may be a blue light emitting layer which includes a blue fluorescent host and a blue fluorescent dopant, thereby emitting blue light.

In embodiments, in order to improve the light emission efficiency and lifetime of the light emitting element LD, the eleventh light emitting layer EML11 (or first light emitting layer EML1), the twenty-first light emitting layer EML21 (or second light emitting layer EML2), and the thirty-first light emitting layer EML31 (or third light emitting layer EML3) in the first sub-pixel SP1 (or red sub-pixel) and the second sub-pixel SP2 (or green sub-pixel) may be provided as common layers including a same material. For example, in each of the first and second sub-pixels SP1 and SP2, the eleventh light emitting layer EML11, the twenty-first light emitting layer EML21, and the thirty-first light emitting layer EML31 may include a host of a green phosphorescent layer and a green phosphorescent dopant, thereby emitting green light. Accordingly, light of a green color may be emitted in the first light emitting structure EMS1 of each of the first and second sub-pixels SP1 and SP2. The first color conversion layer CCP1 may be disposed on the first light emitting structure EMS1 of the first sub-pixel SP1 to convert light of the green color, which is emitted from the first light emitting structure EMS1, into light of a red color, and the light scattering layer instead of the second color conversion layer CCP2 may be disposed on the first light emitting structure EMS1 of the second sub-pixel SP2 to transmit light of the green color, which is emitted from the first light emitting structure EMS1, implementing excellent color reproducibility.

In the third sub-pixel SP3 (or blue sub-pixel), the twelfth light emitting layer EML12 (or first light emitting layer EML1), the twenty-second light emitting layer EML22 (or second light emitting layer EML2), and the thirty-second light emitting layer EML32 (or third light emitting layer EML3) may include a blue fluorescent host and a blue fluorescent dopant, thereby emitting blue light. However, the disclosure is not limited thereto. In some embodiments, the twelfth light emitting layer EML12, the twenty-second light emitting layer EML22, and the thirty-second light emitting layer EML32 may include a blue phosphorescent host and a blue phosphorescent dopant, thereby emitting blue light.

In each of the first and second sub-pixels SP1 and SP2, the twenty-first injection layer IL21 may be disposed between the thirty-first hole transport component HTU31 of the thirty-first light emitting component EU31 and the upper electrode UE. In the third sub-pixel SP3, the twenty-second injection layer IL22 may be disposed between the thirty-second hole transport component HTU32 of the thirty-second light emitting component EU32 and the upper electrode UE.

The twenty-first injection layer IL21 (or second injection layer IL2) may serve as a hole injection layer which lowers an injection barrier between the upper electrode UE and the thirty-first hole transport component HTU31 so as to allow holes to be readily injected from the upper electrode UE to the thirty-first hole transport component HTU31. The twenty-second injection layer IL22 (or second injection layer IL2) may serve as a hole injection layer which lowers an injection barrier between the upper electrode UE and the thirty-second hole transport component HTU32 so as to allow holes to be readily injected from the upper electrode UE to the thirty-second hole transport component HTU32.

In embodiments, the twenty-first injection layer IL21 and the twenty-second injection layer IL22 may include at least one of a hole injection material and a p-type dopant. For example, the twenty-first injection layer IL21 and the twenty-second injection layer IL22 may include an organic material having a hole injection characteristic and a p-type dopant having a highest occupied molecular orbital (HOMO) in a range of about-9.5 eV to about-1.5 eV. The p-type dopant may include 4-([[2,3-bis [cyano-(4-cyano-2,3,5,6-tetrafluorophenyl)methylidene]cyclopropylidene]-cyanomethyl]-2,3,5,6-tetrafluorobenzonitrile)-malononitrile (NDP-9), but the disclosure is not limited thereto. In some embodiments, the p-type dopant may include at least one of 2,3,5,6-tetrafluoro-7,7′,8,8′-tetracyanoquinodimethane (F4-TCNQ), 2,2′-(perfluoronaphthalene-2,6-diylidene)dimalononitrile (F6-TCNNQ), 1,4,5,8,9,11-hexaazatriphenylene-hexacarbonitrile (HAT-CN), and poly(triarylamine) (PTAA).

Each of the twenty-first injection layer IL21 and the twenty-second injection layer IL22 may be configured as a double layer including a first layer FL and a second layer SL. For example, each of the twenty-first injection layer IL21 and the twenty-second injection layer IL22 may be configured as a double layer including a first layer FL including an organic layer having a hole injection characteristic and a p-type dopant such as the above-described NDP-9 and a second layer SL doped with an inorganic metal oxide. The second layer SL may be a layer doped with an inorganic metal oxide such as WOₓ, MoOₓ or VOₓ so as to improve an interface characteristic with the upper electrode UE as an anode electrode, but the disclosure is not limited thereto. The second layer SL may have a thickness d in a range of about 5 Å to about 500 Å, but the disclosure is not limited thereto.

In some embodiments, the twenty-first injection layer IL21 and the twenty-second injection layer IL22 may include different materials. For example, the twenty-first injection layer IL21 may include a p-type dopant such as NDP-9, which has excellent conductivity, in a hole injection material selected (appropriate) from hole injection materials. A doping concentration of the NDP-9 may be in a range of about 0.5% to about 30%, but the disclosure is not limited thereto. The twenty-second injection layer IL22 may include at least one of a compound made of a post transition metal and a metalloid, a compound made of a transition metal and halogen, a post transition metal, and a metalloid in a hole injection material selected from hole injection materials. The post transition metal may include, for example, at least one of aluminum (Al), gallium (Ga), indium (In), thallium (Tl), tin (Sn), lead (Pb), flerovium (Fl), bismuth (Bi), and polonium (Po), but the disclosure is not limited thereto. The metalloid may include, for example, at least one of boron (B), silicon (Si), germanium (Ge), arsenic (As), antimony (Sb), tellurium (Te), and astatine (At), but the disclosure is not limited thereto. The compound made of a post transition metal and a metalloid may include, for example, at least one of Bi₂Te₃, BiₓTe_{y}, Sb₂Te₃, In₂Te₃, Ga₂Te₃, Al₂Te₃, Tl₂Te₃, As₂Te₃, GeSbTe, SnTe, PbTe, SiTe, GeTe, FlTe, SiGe, AlInSb, AlGaSb, AlAsSb, GaAs, InSb, AlSb, AlAs, AlₓInₓSb, AlₓIn₍₁₋ₓ₎Sb, AlSb, GaSb, and AlInGaAs.

The eleventh intermediate layer CGL 11 (or first intermediate layer CGL1) may be provided in the form of a charge generation layer, and be disposed between the eleventh light emitting component EU11 and the twenty-first light emitting component EU21 to connect the eleventh light emitting component EU11 and the twenty-first light emitting component EU21 to each other. The eleventh intermediate layer CGL11 may function to adjust a charge balance between the eleventh light emitting component EU11 and the twenty-first light emitting component EU21.

The eleventh intermediate layer CGL11 may include the eleventh p-type charge generation layer p_CGL11 (or first p-type charge generation layer) and the eleventh n-type charge generation layer n_CGL11 (or first n-type charge generation layer) disposed on the eleventh p-type charge generation layer p_CGL11. The eleventh p-type charge generation layer p_CGL11 may be disposed between the eleventh hole transport component HTU11 and the eleventh n-type charge generation layer n_CGL11, and the eleventh n-type charge generation layer n_CGL11 may be disposed between the eleventh p-type charge generation layer p_CGL11 and the twenty-first electron transport component ETU21. The eleventh p-type charge generation layer p_CGL11 may provide holes to the eleventh hole transport component HTU11. The eleventh n-type charge generation layer n_CGL11 may provide electrons to the twenty-first electron transport component ETU21.

The twelfth intermediate layer CGL21 (or second intermediate layer CGL2) may be provided in the form of a charge generation layer, and be disposed between the twelfth light emitting component EU12 and the twenty-second light emitting component EU22 to connect the twelfth light emitting component EU12 and the twenty-second light emitting component EU22 to each other. The twelfth intermediate layer CGL21 may function to adjust a charge balance between the twelfth light emitting component EU12 and the twenty-second light emitting component EU22.

The twelfth intermediate layer CGL12 may include the twelfth p-type charge generation layer p_CGL12 (or first p-type charge generation layer) and the twelfth n-type charge generation layer n_CGL12 (or first n-type charge generation layer) disposed on the twelfth p-type charge generation layer p_CGL12. The twelfth p-type charge generation layer p_CGL12 may be disposed between the twelfth hole transport component HTU12 and the twelfth n-type charge generation layer n_CGL12, and the twelfth n-type charge generation layer n_CGL12 may be disposed between the twelfth p-type charge generation layer p_CGL12 and the twenty-second electron transport component ETU22. The twelfth p-type charge generation layer p_CGL 12 may provide holes to the twelfth hole transport component HTU12. The twelfth n-type charge generation layer n_CGL12 may provide electrons to the twenty-second electron transport component ETU22.

In embodiments, the eleventh intermediate layer CGL11 and the twelfth intermediate layer CGL12 may be separated from each other by the bank BNK. In other words, the eleventh intermediate layer CGL11 of the first and second sub-pixels SP1 and SP2 and the twelfth intermediate layer CGL12 of the third sub-pixel SP3 may not be connected to each other but may be separated from each other.

The twenty-first intermediate layer CGL21 (or first intermediate layer CGL1) may be provided in the form of a charge generation layer, and be disposed between the twenty-first light emitting component EU21 and the thirty-first light emitting component EU31 to connect the twenty-first light emitting component EU21 and the thirty-first light emitting component EU31 to each other. The twenty-first intermediate layer CGL21 may function to adjust a charge balance between the twenty-first light emitting component EU21 and the thirty-first light emitting component EU31.

The twenty-first intermediate layer CGL21 may include the twenty-first p-type charge generation layer p_CGL21 (or second p-type charge generation layer) and the twenty-first n-type charge generation layer n_CGL21 (or second n-type charge generation layer) disposed on the twenty-first p-type charge generation layer p_CGL21. The twenty-first p-type charge generation layer p_CGL21 may be disposed between the twenty-first hole transport component HTU21 and the twenty-first n-type charge generation layer n_CGL21, and the twenty-first n-type charge generation layer n_CGL21 may be disposed between the twenty-first p-type charge generation layer p_CGL21 and the thirty-first electron transport component ETU31. The twenty-first p-type charge generation layer p_CGL21 may provide holes to the twenty-first hole transport component HTU21. The twenty-first n-type charge generation layer n_CGL21 may provide electrons to the thirty-first electron transport component ETU31.

The twenty-second intermediate layer CGL22 (or second intermediate layer CGL2) may be provided in the form of a charge generation layer, and be disposed between the twenty-second light emitting component EU22 and the thirty-second light emitting component EU32 to connect the twenty-second light emitting component EU22 and the thirty-second light emitting component EU32 to each other. The twenty-second intermediate layer CGL22 may function to adjust a charge balance between the twenty-second light emitting component EU22 and the thirty-second light emitting component EU32.

The twenty-second intermediate layer CGL22 may include the twenty-second p-type charge generation layer p_CGL22 (or second p-type charge generation layer) and the twenty-second n-type charge generation layer n_CGL22 (or second n-type charge generation layer) disposed on the twenty-second p-type charge generation layer p_CGL22. The twenty-second p-type charge generation layer p_CGL22 may be disposed between the twenty-second hole transport component HTU22 and the twenty-second n-type charge generation layer n_CGL22, and the twenty-second n-type charge generation layer n_CGL22 may be disposed between twenty-second p-type charge generation layer p_CGL22 and the thirty-second electron transport component ETU32. The twenty-second p-type charge generation layer p_CGL22 may provide holes to the twenty-second hole transport component HTU22. The twenty-second n-type charge generation layer n_CGL22 may provide electrons to the thirty-second electron transport component ETU32.

In embodiments, the twenty-first intermediate layer CGL21 and the twenty-second intermediate layer CGL22 may be separated from each other by the bank BNK. In other words, the twenty-first intermediate layer CGL21 of the first and second sub-pixels SP1 and SP2 and the twenty-second intermediate layer CGL22 of the third sub-pixel SP3 may not be connected to each other but may be separated from each other.

In embodiments, the eleventh n-type charge generation layer n_CGL11, the twelfth n-type charge generation layer n_CGL12, the twenty-first n-type charge generation layer n_CGL21, and the twenty-second n-type charge generation layer n_CGL22 may include an alkali metal, an alkali earth metal, a lanthanide-based metal, or a combination thereof, but the disclosure is not limited thereto. For example, the eleventh n-type charge generation layer n_CGL11, the twelfth n-type charge generation layer n_CGL12, the twenty-first n-type charge generation layer n_CGL21, and the twenty-second n-type charge generation layer n_CGL22 may include an n-type dopant made of at least one of an organic material having an electron transport characteristic and a metal having a work function in a range of about-4.0 eV to about −1.0 eV. The metal may include ytterbium (Yb), lithium (Li), and the like.

The eleventh and twenty-first p-type charge generation layers p_CGL11 and p_CGL21 provided in the first and second sub-pixels SP1 and SP2 may include a same material. The twelfth and twenty-second p-type charge generation layers p_CGL12 and p_CGL22 provided in the third sub-pixel SP3 may include a same material.

The eleventh and twenty-first p-type charge generation layers p_CGL11 and p_CGL21 provided in the first and second sub-pixels SP1 and SP2 and the twelfth and twenty-second p-type charge generation layers p_CGL 12 and p_CGL22 provided in the third sub-pixel SP3 may include different materials. For example, the eleventh and twenty-first p-type charge generation layers p_CGL11 and p_CGL21 may include an organic material having a hole transport characteristic and a p-type dopant such as NDP-9, which has excellent conductivity. The twelfth and twenty-second p-type charge generation layers p_CGL12 and p_CGL22 may include an organic material having a hole transport characteristic and an inorganic metal material having an excellent charge generation characteristic as compared with the NDP-9. The inorganic metal material of the twelfth and twenty-second p-type charge generation layers p_CGL12 and p_CGL22 may include, for example, at least one of a compound made of a post transition metal and a metalloid, a compound made of a transition metal and halogen, a post transition metal, and a metalloid. The post transition metal may include, for example, at least one of aluminum (Al), gallium (Ga), indium (In), thallium (Tl), tin (Sn), lead (Pb), flerovium (Fl), bismuth (Bi), and polonium (Po), but the disclosure is not limited thereto. The metalloid may include, for example, at least one of boron (B), silicon (Si), germanium (Ge), arsenic (As), antimony (Sb), tellurium (Te), and astatine (At), but the disclosure is not limited thereto. The compound made of a post transition metal and a metalloid may include, for example, at least one of Bi₂Te₃, BiₓTe_{y}, Sb₂Te₃, In₂Te₃, Ga₂Te₃, Al₂Te₃, Tl₂Te₃, As₂Te₃, GeSbTe, SnTe, PbTe, SiTe, GeTe, FlTe, SiGe, AlInSb, AlGaSb, AlAsSb, GaAs, InSb, AlSb, AlAs, AlₓInₓSb, AlₓIn₍₁₋ₓ₎Sb, AlSb, GaSb, and AlInGaAs.

In embodiments, the charge generation characteristic in the twelfth and twenty-second p-type charge generation layers p_CGL 12 and p_CGL22 may be improved by adjusting a doping concentration of the inorganic metal material. For example, in case that the inorganic metal material is a compound made of a post transition metal and a metalloid, such as bismuth telluride (Bi₂Te₃), a doping concentration of the bismuth telluride may be in a range of about 0.1% to about 50%. In case that the inorganic metal material is a compound made of a transition metal and halogen, a doping concentration of the compound may be in a range of about 0.1% to about 50%. In case that the electrical conductivity of the p-type dopant included in the twelfth and twenty-second p-type charge generation layers p_CGL12 and p_CGL22 is increased, an injection barrier between components disposed adjacent to each other (e.g., the twelfth and twenty-second hole transport components HTU12 and HTU22 and the twelfth and twenty-second n-type charge generation layers n_CGL12 and n_CGL22) may be adjusted, thereby improving the charge generation characteristic in the twelfth and twenty-second intermediate layers CGL12 and CGL22.

Current characteristic degrees of a p-type charge generation layer according to a material, a doping concentration, and the like will be described with reference to FIGS. 8 and 9.

In FIG. 8, Comparative Example represents a current characteristic according to a voltage of a p-type charge generation layer obtained by doping a host (e.g., a material having a hole transport characteristic) with NDP-9 by 10%, Embodiment 1 represents a current characteristic according to a voltage of a p-type charge generation layer obtained by doping the same host as the Comparative Example with bismuth telluride by 5% and CuI by 10%, Embodiment 2 represents a current characteristic according to a voltage of a p-type charge generation layer obtained by doping the same host as the Comparative Example with bismuth telluride by 10% and CuI by 10%, and Embodiment 3 represents a current characteristic according to a voltage of a p-type charge generation layer obtained by doping the same host as the Comparative Example with bismuth telluride by 15% and CuI by 10%.

In FIG. 9, Comparative Example represents a current characteristic according to a voltage of a p-type charge generation layer obtained by doping a host (e.g., a material having a hole transport characteristic) with NDP-9 by 10%, Embodiment 4 represents a current characteristic according to a voltage of a p-type charge generation layer obtained by doping the same host as the Comparative Example with bismuth telluride by 10% and CuI by 5%, Embodiment 5 represents a current characteristic according to a voltage of a p-type charge generation layer obtained by doping the same host as the Comparative Example with bismuth telluride by 10% and CuI by 10%, and Embodiment 6 represents a current characteristic according to a voltage of a p-type charge generation layer obtained by doping the same host as the Comparative Example with bismuth telluride by 10% and CuI by 15%.

As shown in each of FIGS. 8 and 9, it can be seen that the p-type charge generation layer of each of the Embodiment 1, the Embodiment 2, the Embodiment 3, the Embodiment 4, the Embodiment 5, and the Embodiment 6 generates a large amount of current even at a voltage relatively lower than the voltage of the p-type charge generation layer of the Comparative Example. Specifically, it can be seen that the p-type charge generation layer corresponding to each of the Embodiment 1, the Embodiment 2, the Embodiment 3, the Embodiment 4, the Embodiment 5, and the Embodiment 6 generates a large amount of current at a voltage relatively lower than the voltage of the p-type charge generation layer of the Comparative Example in each of a reverse bias area (or a range in which a reverse voltage is applied) and a forward bias area (or a range in which a forward voltage is applied). Accordingly, it can be seen that a p-type charge generation layer doped with an inorganic metal material including bismuth telluride and CuI has an excellent charge generation characteristic as compared with a p-type charge generation layer doped with NDP-9.

In the above-described Embodiments, by reflecting simulation results shown in FIGS. 8 and 9, p-type charge generation layers, e.g., the twelfth and twenty-second p-type charge generation layers p_CGL12 and p_CGL22 in the third sub-pixel SP3 emitting blue light, including a blue fluorescent host and a blue fluorescent dopant, may be doped with an inorganic metal material including bismuth telluride and CuI instead of NDP-9. A charge generation characteristic in the third sub-pixel SP3 may be increased as compared with the first and second sub-pixels SP1 and SP2. Due to material characteristics, the light emission efficiency of the twelfth, twenty-second, and thirty-second light emitting elements EML12, EML22, and EML32 may be deteriorated as compared with the eleventh, twenty-first, and thirty-first light emitting elements EML11, EML21, and EML31. However, the charge generation characteristic in the twelfth and twenty-second p-type charge generating layers p_CGL12 and p_CGL22 adjacent to the twelfth, twenty-second, and thirty-second light emitting elements EML12, EML22, and EML32 may be improved, so that the light emission efficiency of the third sub-pixel SP3 may become similar to the light emission efficiency of the first and second sub-pixels SP1 and SP2.

In accordance with the above-described embodiment, the eleventh injection layer IL11 may be disposed between the first lower electrode LE1 and the eleventh electron transport component ETU11 and between the second lower electrode LE2 and the eleventh electron transport component ETU11, and the twelfth injection layer IL12 may be disposed between the third lower electrode LE3 and the twelfth electron transport component ETU12, so that the injection barrier between the lower electrode and the electron transport component may be lowered. The twenty-first injection layer IL21 may be disposed between the upper electrode UE and the thirty-first hole transport component HTU31, and the twenty-second injection layer IL22 having an improved charge generation characteristic as compared with the twenty-first injection layer IL21 may be disposed between the upper electrode UE and the thirty-second hole transport component HTU32, so that the injection barrier between the upper electrode UE and the hole transport component may be lowered. Accordingly, element characteristics of the first light emitting element LD1, the second light emitting element LD2, and the third light emitting element LD3, which have the inverted structure, may be improved, so that the light emission efficiency of the first to third sub-pixels SP1 to SP3 may be improved.

In accordance with the above-described embodiments, the bank BNK having liquid repellent properties may be disposed on the pixel defining layer PDL between the second sub-pixel SP2 and the third sub-pixel SP3 and between the third sub-pixel SP3 and the first sub-pixel SP1, so that at least a portion of the light emitting structure EMS (or first light emitting structure EMS1) of each of the first and second sub-pixels SP1 and SP2 and at least a portion of the light emitting structure EMS (or second light emitting structure EMS2) of the third sub-pixel SP3 may be separated from each other. Accordingly, the p-type charge generation layer of the first light emitting structure EMS1 and the p-type charge generation layer of the second light emitting structure EMS2 may be readily configured with different materials, and the twenty-first injection layer IL21 (or hole injection layer) of the first light emitting structure EMS1 and the twenty-second injection layer IL22 (or hole injection layer) of the second light emitting structure EMS2 may be readily configured with different materials.

Particularly, in the above-described embodiments, the p-type charge generation layer and the twenty-first injection layer IL21 of the first light emitting structure EMS1 may be configured by doping a hole transport material with a NDP-9-based p-type dopant, and the p-type charge generation layer and the twenty-second injection layer IL22 of the second light emitting structure EMS2 may be configured by doping a hole transport material with an inorganic metal material described in the above-described embodiments, so that the charge generation characteristic in the second light emitting structure EMS may be improved, thereby allowing the light emission efficiency of the third sub-pixel SP3 to become similar to the light emission efficiency of the first and second sub-pixels SP1 and SP2.

In the existing display device, a light emitting structure of each of a red sub-pixel, a green sub-pixel, and a blue sub-pixel was designed to commonly include a blue light emitting layer emitting blue light, including a fluorescent blue host and a fluorescent blue dopant. Particularly, because the efficiency with which blue light emitted from the light emitting structure of the green sub-pixel was converted into green light by a green quantum dot located on the top of the light emitting structure was low, the light emission efficiency of the green sub-pixel was decreased, and therefore, the reliability of each pixel was deteriorated.

However, in the above-described embodiments, the first light emitting structure EMS1 of the first sub-pixel SP (or red sub-pixel) and the second sub-pixel SP2 (or green sub-pixel) may be designed to include a green light emitting layer, and the second light emitting structure EMS2 of the third sub-pixel SP3 may be designed to emit blue light, thereby improving the light emission efficiency with which light of a green color, which is emitted from the first light emitting structure EMS1 of the second sub-pixel SP2, into light of a green color having excellent color reproducibility in the second color conversion layer CCP2 (or the light scattering layer) disposed on the top of the first light emitting structure EMS1.

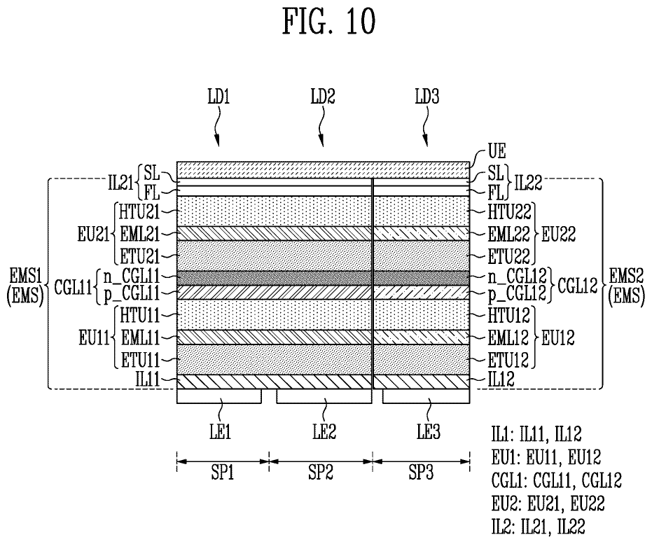

In the above-described embodiments, it has been described that the light emitting structure EMS has a tandem structure in which the first light emitting component EU1, the second light emitting component EU2, and the third light emitting component EU3 are stacked. However, the disclosure is not limited thereto. Hereinafter, a tandem structure in which a first light emitting component EU1 and a second light emitting component EU2 are stacked will be described with reference to FIG. 10.

FIG. 10 is a schematic cross-sectional view schematically illustrating another embodiment of the first to third light emitting elements LD1, LD2, and LD3 shown in FIG. 5.

In FIG. 10, portions different from those of the above-described embodiments will be described to avoid redundancy.

Referring to FIGS. 5 and 10, each of first to third light emitting elements LD1 to LD3 may be a light emitting element having an inverted structure, which includes a lower electrode (or cathode electrode), a light emitting structure EMS, and an upper electrode UE (or anode electrode). Light emitting structures EMS (hereinafter, referred to as a “first light emitting structure EMS1”) of first and second sub-pixels SP1 and SP2 may be connected to each other. A light emitting structure EMS (hereinafter, referred to as a “second light emitting structure EMS2”) of a third sub-pixel SP3 may be separated from the first light emitting structure EMS1 of the first and second sub-pixels SP1 and SP2.

The first light emitting structure EMS1 may include an eleventh injection layer IL11 (or first injection layer IL1), an eleventh light emitting component EU11 (or a first light emitting component EU1), an eleventh intermediate layer CGL11 (or first intermediate layer CGL1), a twenty-first light emitting component EU21 (or second light emitting component EU2), and a twenty-first injection layer IL21 (or second injection layer IL2). The twenty-first injection layer IL21 may be disposed between a twenty-first hole transport component HTU21 of the twenty-first light emitting component EU21 and the upper electrode UE (or anode electrode).

The second light emitting structure EMS2 may include a twelfth injection layer IL12 (or first injection layer IL1), a twelfth light emitting component EU21 (or first light emitting component EU1), a twelfth intermediate layer CGL12 (or first intermediate layer CGL1), a twenty-second light emitting component EU22 (or second light emitting component EU2, and a twenty-second injection layer IL22 (or second injection layer IL2). The twenty-second injection layer IL22 may be disposed between a twenty-second hole transport component HTU22 of the twenty-second light emitting component EU22 and the upper electrode UE.

In embodiments, each of the twenty-first injection layer IL21 and the twenty-second injection layer IL22 may be configured as a double layer including a first layer FL and a second layer SL.

The twenty-first injection layer IL21 and the twenty-second injection layer IL22 may include a same material. For example, the twenty-first injection layer IL21 and the twenty-second injection layer IL22 may include an organic material having a hole injection characteristic and a p-type dopant having a highest occupied molecular orbital (HOMO) in a range of about-9.5 eV to about-1.5 eV.

In some embodiments, the twenty-first injection layer IL21 and the twenty-second injection layer IL22 may include different materials. For example, the twenty-first injection layer IL21 may include a p-type dopant in at least one hole injection material. The p-type dopant may include at least one of NDP-9, 2,3,5,6-tetrafluoro-7,7′,8,8′-tetracyanoquinodimethane (F4-TCNQ), 2,2′-(perfluoronaphthalene-2,6-diylidene)dimalononitrile (F6-TCNNQ), 1,4,5,8,9,11-hexaazatriphenylene-hexacarbonitrile (HAT-CN), and poly(triarylamine) (PTAA). For example, the twenty-first injection layer IL21 may include a p-type dopant such as NDP-9. The twenty-second injection layer IL22 may include at least one of a compound made of a post transition metal and a metalloid, a compound made of a transition metal and halogen, a post transition metal, and a metalloid in at least one hole injection material. The twenty-second injection layer IL22 may have a relatively improved charge generation characteristic as compared with the twenty-first injection layer IL21. In case that the charge generation characteristic in the third sub-pixel SP3 in which the twenty-second injection layer IL22 is located is improved, deterioration of light emission efficiency due to material characteristics of twelfth and twenty-second light emitting layers EML12 and EML22 may be compensated, so that light emission efficiency of the third sub-pixel SP3 may become similar to light emission efficiency of the first and second sub-pixels SP1 and SP2.

The eleventh intermediate layer CGL11 may include an eleventh p-type charge generation layer p_CGL11 (or first p-type charge generation layer) and an eleventh n-type charge generation layer n_CGL11 (or first n-type charge generation layer), which are disposed between an eleventh hole transport component HTU11 and a twenty-first electron transport component ETU21. The twelfth intermediate layer CGL12 may include a twelfth p-type charge generation layer p_CGL12 (or first p-type charge generation layer) and a twelfth n-type charge generation layer n_CGL12 (or first n-type charge generation layer), which are disposed between a twelfth hole transport component HTU12 and a twenty-second electron transport component ETU22.

In embodiments, the eleventh n-type charge generation layer n_CGL11 and the twelfth n-type charge generation layer n_CGL12 may include an n-type dopant made of at least one of an organic material having an electron transport characteristic and a metal having a work function in a range of about-4.0 eV to about-1.0 eV. The metal may include ytterbium (Yb), lithium (Li), and the like. For example, the eleventh n-type charge generation layer n_CGL11 and the twelfth n-type charge generation layer n_CGL12 may include a same material, but the disclosure is not limited thereto.

The eleventh p-type charge generation layer p_CGL11 and the twelfth p-type charge generation layer p_CGL12 may include different materials. For example, the eleventh p-type charge generation layer p_CGL11 may include an organic material having a hole transport characteristic and a p-type dopant having excellent conductivity. The p-type dopant of the eleventh p-type charge generation layer p_CGL11 may include at least one of NDP-9, 2,3,5,6-tetrafluoro-7,7′,8,8′-tetracyanoquinodimethane (F4-TCNQ), 2,2′-(perfluoronaphthalene-2,6-diylidene)dimalononitrile (F6-TCNNQ), 1,4,5,8,9,11-hexaazatriphenylene-hexacarbonitrile (HAT-CN), and poly(triarylamine) (PTAA). For example, the eleventh p-type charge generation layer p_CGL11 may include a p-type dopant such as NDP-9. The twelfth p-type charge generation layer p_CGL12 may include an organic material having a hole transport characteristic and an inorganic metal material having an excellent charge generation characteristic as compared with NDP-9. The inorganic metal material of the twelfth p-type charge generation layer p_CGL12 may include at least one of a compound made of a post transition metal and a metalloid, a compound made of a transition metal and halogen, a post transition metal, and a metalloid. The twelfth p-type charge generation layer p_CGL12 may have a relatively improved charge generation characteristic as compared with the eleventh p-type charge generation layer p_CGL11. In case that the charge generation characteristic in the third sub-pixel SP3 in which the twelfth p-type charge generation layer p_CGL12 is located is improved, deterioration of light emission efficiency due to material characteristics of the twelfth and twenty-second light emitting layers EML12 and EML22 may be compensated, so that light emission efficiency of the third sub-pixel SP3 may become similar to light emission efficiency of the first and second sub-pixels SP1 and SP2.

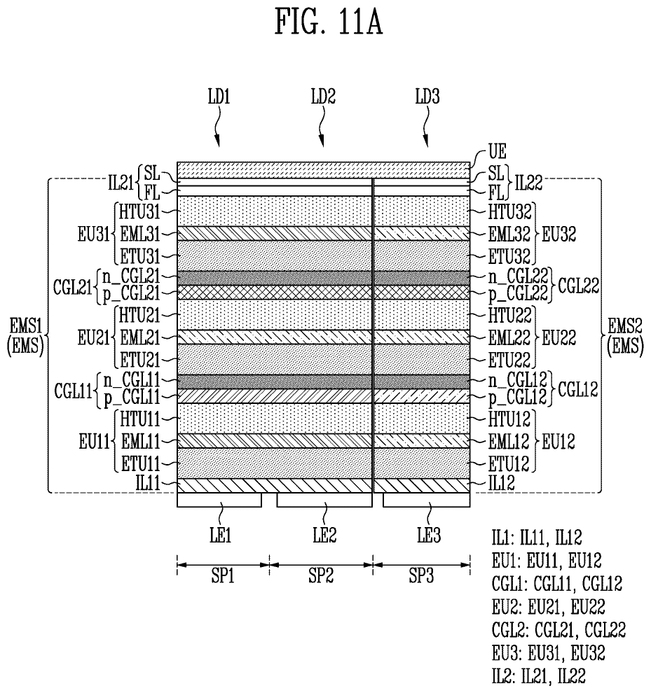

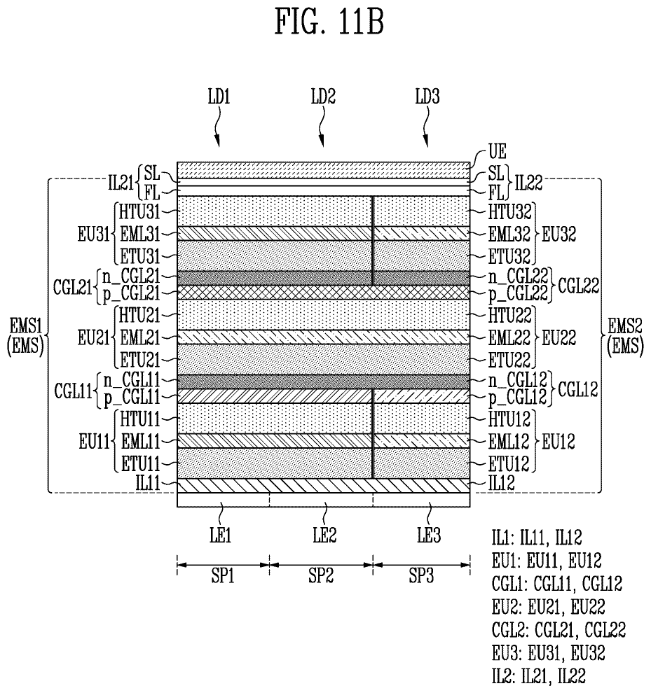

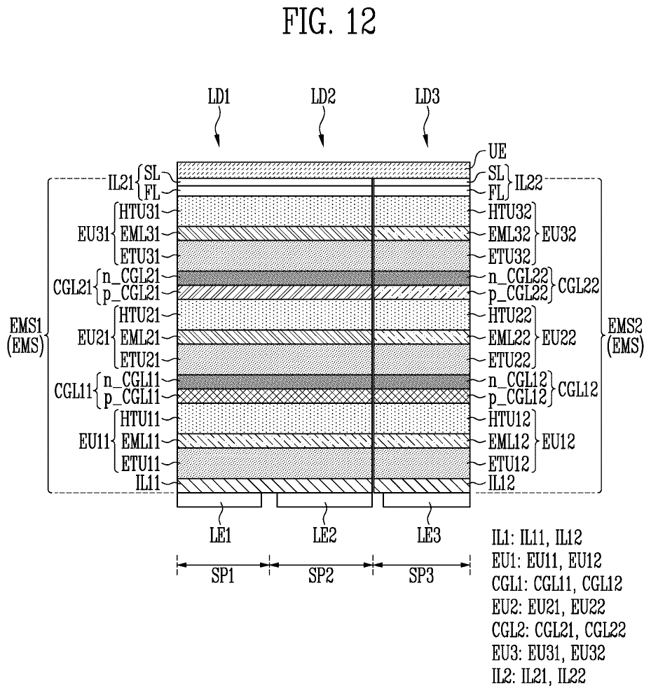

FIGS. 11A, 11B, and 12 are schematic cross-sectional views schematically illustrating still another embodiment of the first to third light emitting elements LD1, LD2, and LD3 shown in FIG. 5.

In FIGS. 11A, 11B, and 12, portions different from those of the above-described embodiments will be described to avoid redundancy.

Referring to FIGS. 5, 11A, and 11B, each of first to third light emitting elements LD1 to LD3 may be a light emitting element having an inverted structure, which includes a lower electrode (or cathode electrode), a light emitting structure EMS, and an upper electrode UE (or anode electrode). A first lower electrode LE1 of the first light emitting element LD1, a second lower electrode LE2 of the second light emitting element LD2, and a third lower electrode LE3 of the third light emitting element LD3 may be electrically separated from each other.

In an embodiment, light emitting structures EMS (hereinafter, referred to as a “first light emitting structure EMS1”) of first and second sub-pixels SP1 and SP2 may be connected to each other. A light emitting structure EMS (hereinafter, referred to as a “second light emitting structure EMS2”) of a third sub-pixel SP3 may be separated from at least some components of the first light emitting structure EMS1.

The first light emitting structure EMS1 may include an eleventh injection layer IL11 (or first injection layer IL1), an eleventh light emitting component EU11 (or first light emitting component EU1), an eleventh intermediate layer CGL11 (or first intermediate layer CGL11), a twenty-first light emitting component EU21 (or second light emitting component EU2), a twenty-first intermediate layer CGL21 (or second intermediate layer CGL2), a thirty-first light emitting component EU31 (or third light emitting component EU3), and a twenty-first injection layer IL21 (or second injection layer IL2). The twenty-first injection layer IL21 may be disposed between a thirty-first hole transport component HTU31 of the thirty-first light emitting component EU31 and the upper electrode UE (or anode electrode).

The second light emitting structure EMS may include a twelfth injection layer IL12 (or first injection layer IL2), a twelfth light emitting component EU12 (or first light emitting component EU1), a twelfth intermediate layer CGL12 (or first intermediate layer CGL1), a twenty-second light emitting component EU22 (or second light emitting component EU2), a twenty-second intermediate layer CGL22 (or second intermediate layer CGL2), a thirty-second light emitting component EU32 (or third light emitting component EU3), and a twenty-second injection layer IL22 (or second injection layer IL2). The twenty-second injection layer IL22 may be disposed between a thirty-second hole transport component HTU32 of the thirty-second light emitting component EU32 and the upper electrode UE (or anode electrode).

The eleventh injection layer IL11 and the twelfth injection layer IL12 may include a same material and be formed through a same process. The eleventh injection layer IL11 and the twelfth injection layer IL12 may be provided not to be separated from each other but to be connected to each other. The eleventh injection layer IL11 and the twelfth injection layer IL12 may correspond to a common layer commonly provided in the first and second light emitting structures EMS1 and EMS2. As shown in FIG. 11A, the eleventh injection layer IL11 and the twelfth injection layer IL12 may be separated from each other, but the disclosure is not limited thereto. In some embodiments, as shown in FIG. 11B, the eleventh injection layer IL11 and the twelfth injection layer IL12 may be connected to each other to be provided as a common layer. The eleventh injection layer IL11 and the twelfth injection layer IL12 may be integrally formed.

The twenty-first injection layer IL21 and the twenty-second injection layer IL22 may include a same material and be formed through a same process. The twenty-first injection layer IL21 and the twenty-second injection layer IL22 may be provided not to be separated from each other but to be connected to each other. The twenty-first injection layer IL21 and the twenty-second injection layer IL22 may correspond to a common layer commonly provided in the first and second light emitting structures EMS1 and EMS2. As shown in FIG. 11A, the twenty-first injection layer IL21 and the twenty-second injection layer IL22 may be separated from each other, but the disclosure is not limited thereto. In some embodiments, as shown in FIG. 11B, the twenty-first injection layer IL21 and the twenty-second injection layer IL22 may be connected to each other to be provided as a common layer. The twenty-first injection layer IL21 and the twenty-second injection layer IL22 may be integrally formed.

Each of an eleventh light emitting layer EML11 of the eleventh light emitting component EU11 and a thirty-first light emitting layer EML31 of the thirty-first light emitting component EU31 may be a green light emitting layer which includes a host of a green phosphorescent layer and a green phosphorescent dopant, thereby emitting light of a green color. Each of a twelfth light emitting layer EML12 of the twelfth light emitting component EU12 and a thirty-second light emitting layer EML32 of the thirty-second light emitting component EU32 may be a blue light emitting layer which includes a blue phosphorescent host and a blue phosphorescent dopant, thereby emitting light of a blue color.

In embodiments, a twenty-first light emitting layer EML21 of the twenty-first light emitting component EU21 and a twenty-second light emitting layer EML22 of the twenty-second light emitting component EU22 may include a same material. For example, each of the twenty-first light emitting layer EML21 and the twenty-second light emitting layer EML22 may be a blue light emitting layer which includes a blue fluorescent host and a blue fluorescent dopant, thereby emitting light of a blue color. Light of a green color and light of a blue color may be mixed and emitted in the first light emitting structure EMS1, and light of a blue color may be emitted in the second light emitting structure EMS2. In case that light of a green color and light of a blue color are mixed and emitted in the first light emitting structure EMS1, the second color conversion layer CCP2 may be disposed on the first light emitting structure EMS1 in the second sub-pixel SP2 to convert the light into light of a green color having excellent color reproducibility, thereby emitting the converted light to the second color filter CF2.

In case that the twenty-first light emitting layer EML21 and the twenty-second light emitting layer EML22 are blue light emitting layers including a same material, the twenty-first light emitting layer EML21 and the twenty-second light emitting layer EML22 may be provided not to be separated from each other but to be connected to each other. For example, the twenty-first light emitting layer EML21 and the twenty-second light emitting layer EML22 may correspond to a common layer commonly provided in the first and second light emitting structures EMS1 and EMS2. In FIG. 11A, for convenience, it is illustrated that the twenty-first light emitting layer EML21 and the twenty-second light emitting layer EML22 are separated from each other. However, the disclosure is not limited thereto. In some embodiments, as shown in FIG. 11B, the twenty-first light emitting layer EML21 and the twenty-second light emitting layer EML22 may be connected to each other to be provided as a common layer. The twenty-first light emitting layer EML21 and the twenty-second light emitting layer EML22 may be integrally formed.

A twenty-first electron transport component ETU21 disposed on the bottom of the twenty-first light emitting layer EML21 and a twenty-second electron transport component ETU22 disposed on the bottom of the twenty-second light emitting layer EML22 may include a same material. The twenty-first electron transport component ETU21 and the twenty-second electron transport component ETU22 may be provided not to be separated from each other but to be connected to each other. For example, the twenty-first electron transport component ETU21 and the twenty-second electron transport component ETU22 may correspond to a common layer commonly provided in the first and second light emitting structures EMS1 and EMS2. In FIG. 11A, for convenience, it is illustrated that the twenty-first electron transport component ETU21 and the twenty-second electron transport component ETU22 are separated from each other. However, the disclosure is not limited thereto. In some embodiments, as shown in FIG. 11B, the twenty-first electron transport component ETU21 and the twenty-second electron transport component ETU22 may be connected to each other to be provided as a common layer. The twenty-first electron transport component ETU21 and the twenty-second electron transport component ETU22 may be integrally formed.

A twenty-first hole transport component HTU21 disposed on the top of the twenty-first light emitting layer EML21 and a twenty-second hole transport component HTU22 disposed on the top of the twenty-second light emitting layer EML22 may include a same material. The twenty-first hole transport component HTU21 and the twenty-second hole transport component HTU22 may be provided not to be separated from each other but to be connected to each other. For example, the twenty-first hole transport component HTU21 and the twenty-second hole transport component HTU22 may correspond to a common layer commonly provided in the first and second light emitting structures EMS1 and EMS2. In FIG. 11A, for convenience, it is illustrated that the twenty-first hole transport component HTU21 and the twenty-second hole transport component HTU22 are separated from each other. However, the disclosure is not limited thereto. In some embodiments, as shown in FIG. 11B, the twenty-first hole transport component HTU21 and the twenty-second hole transport component HTU22 may be connected to each other to be provided as a common layer. The twenty-first hole transport component HTU21 and the twenty-second hole transport component HTU22 may be integrally formed.

In case that the twenty-first light emitting layer EML21 and the twenty-second light emitting layer EML22 are blue light emitting layers including a same material, a twenty-first p-type charge generation layer p_CGL21 (or second p-type charge generation layer) disposed on the twenty-first light emitting component EU21 and a twenty-second p-type charge generation layer p_CGL22 (or second p-type charge generation layer) disposed on the twenty-second light emitting component EU22 may include a same material. For example, the twenty-first p-type charge generation layer p_CGL21 and the twenty-second p-type charge generation layer p_CGL22 may include an organic material having a hole transport characteristic and an inorganic metal material having an excellent charge generation characteristic as compared with NDP9. The inorganic metal material of the twenty-first p-type charge generation layer p_CGL21 and the twenty-second p-type charge generation layer p_CGL22 may include, for example, at least one of a compound made of a post transition metal and a metalloid, a compound made of a transition metal and halogen, a post transition metal, and a metalloid.

In case that the twenty-first p-type charge generation layer p_CGL21 and the twenty-second p-type charge generation layer p_CGL22 include a same material, the twenty-first p-type charge generation layer p_CGL21 and the twenty-second p-type charge generation layer p_CGL22 may be formed through a same process not to be separated from each other but to be connected to each other as shown in FIG. 11B. The twenty-first p-type charge generation layer p_CGL21 and the twenty-second p-type charge generation layer p_CGL22 may be integrally formed. However, the disclosure is not limited to the above-described embodiment. In some embodiments, although the twenty-first p-type charge generation layer p_CGL21 and the twenty-second p-type charge generation layer p_CGL22 include a same material and are formed through a same process, the twenty-first p-type charge generation layer p_CGL21 and the twenty-second p-type charge generation layer p_CGL22 may be provided to be separated from each other as shown in FIG. 11A due to liquid repellent properties of the bank BNK.

In case that the twenty-first light emitting layer EML21 and the twenty-second light emitting layer EML22 are blue light emitting layers including a same material, an eleventh n-type charge generation layer n_CGL11 (or first n-type charge generation layer) disposed on the bottom of the twenty-first light emitting component EU21 and a twelfth n-type charge generation layer n_CGL12 (or first n-type charge generation layer) disposed on the bottom of the twenty-second light emitting component EU22 may include a same material. For example, the eleventh n-type charge generation layer n_CGL11 and the twelfth n-type charge generation layer n_CGL12 may be doped with an n-type dopant made of at least one of an organic material having an electron transport characteristic and a metal having a work function in a range of about-4.0 eV to about-1.0 eV. The metal of the eleventh n-type charge generation layer n_CGL11 and the twelfth n-type charge generation layer n_CGL12 may include ytterbium (Yb), lithium (Li), and the like.

In case that the eleventh n-type charge generation layer n_CGL11 and the twelfth n-type charge generation layer n_CGL12 include a same material, the eleventh n-type charge generation layer n_CGL11 and the twelfth n-type charge generation layer n_CGL12 may be formed through a same process not to be separated from each other but to be connected to each other as shown in FIG. 11B. The eleventh n-type charge generation layer n_CGL11 and the twelfth n-type charge generation layer n_CGL12 may be integrally formed. However, the disclosure is not limited to the above-described embodiment. In some embodiments, although the eleventh n-type charge generation layer n_CGL11 and the twelfth n-type charge generation layer n_CGL12 include a same material and are formed through a same process, the eleventh n-type charge generation layer n_CGL11 and the twelfth n-type charge generation layer n_CGL12 may be provided to be separated from each other as shown in FIG. 11A.

As described above, in case that the twenty-first light emitting layer EML21 of the twenty-first light emitting component EU21 and the twenty-second light emitting layer EML22 of the twenty-second light emitting component EU22 include a same material, the twenty-first light emitting layer EML21 and the twenty-second light emitting layer EML22 may be formed through a same process. Manufacturing processes of the first light emitting element LD1, the second light emitting element LD2, and the third light emitting element LD3 may be simplified, so that the manufacturing efficiency of the first to third sub-pixels SP1 to SP3 may be improved.

In the above-embodiments, it has been described that the twenty-first light emitting layer EML21 of the twenty-first light emitting component EU21 and the twenty-second light emitting layer EML22 of the twenty-second light emitting component EU22 are blue light emitting layers including a same material. However, the disclosure is not limited thereto. In some embodiments, as shown in FIG. 12, the eleventh light emitting layer EML11 of the eleventh light emitting component EU11 and the twelfth light emitting layer EML12 of the twelfth light emitting component EU12 may be blue light emitting layers including a same material.

In case that the eleventh light emitting layer EML11 of the eleventh light emitting component EU11 and the twelfth light emitting layer EML12 of the twelfth light emitting component EU12 include a same material, the eleventh injection layer IL11 disposed on the bottom of the eleventh light emitting component EU11 and the twelfth injection layer IL12 disposed on the bottom of the twelfth light emitting component EU12 may include a same material. For example, the eleventh injection layer IL11 and the twelfth injection layer IL12 may include an n-type dopant made of at least one of an electron injection material and a metal having a work function in a range of about-4.0 eV to about-1.0 eV. The metal of the eleventh injection layer IL11 and the twelfth injection layer IL12 may include ytterbium (Yb), lithium (Li), and the like.

In case that the eleventh light emitting layer EML11 of the eleventh light emitting component EU11 and the twelfth light emitting layer EML12 of the twelfth light emitting component EU12 include a same material, an eleventh p-type charge generation layer p_CGL11 disposed on the eleventh light emitting component EU11 and a twelfth p-type charge generation layer p_CGL12 disposed on the twelfth light emitting component EU12 may include a same material. For example, the eleventh p-type charge generation layer p_CGL11 and the twelfth p-type charge generation layer p_CGL12 may include an organic material having a hole transport characteristic and an inorganic metal material having an excellent charge generation characteristic as compared with NDP-9. The inorganic metal material of the eleventh p-type charge generation layer p_CGL11 and the twelfth p-type charge generation layer p_CGL12 may include at least one of a compound made of a post transition metal and a metalloid, a compound made of a transition metal and halogen, a post transition metal, and a metalloid.

In case that the eleventh p-type charge generation layer p_CGL11 and the twelfth p-type charge generation layer p_CGL12 include a same material, the eleventh p-type charge generation layer p_CGL11 and the twelfth p-type charge generation layer p_CGL12 may be formed through a same process not to be separated from each other but to be connected to each other. However, the disclosure is not limited thereto. In some embodiments, although the eleventh p-type charge generation layer p_CGL11 and the twelfth p-type charge generation layer p_CGL12 include a same material and are formed through a same process, the eleventh p-type charge generation layer p_CGL11 and the twelfth p-type charge generation layer p_CGL12 may be provided to be separated from each other due to liquid repellent properties of the bank BNK.

In some embodiments, the thirty-first light emitting layer EML31 of the thirty-first light emitting component EU31 and the thirty-second light emitting layer EML32 of the thirty-second light emitting component EU32 may be blue light emitting layers including a same material. The twenty-first injection layer IL21 disposed on the thirty-first light emitting component EU31 and the twenty-second injection layer IL22 disposed on the thirty-second light emitting component EU32 may include a same material. For example, the twenty-first injection layer IL21 and the twenty-second injection layer IL22 may include an organic material having a hole transport characteristic and an inorganic metal material having an excellent charge generation characteristic as compared with NDP-9. The inorganic metal material of the twenty-first injection layer IL21 and the twenty-second injection layer IL22 may include at least one of a compound made of a post transition metal and a metalloid, a compound made of a transition metal and halogen, a post transition metal, and a metalloid.

In case that the thirty-first light emitting layer EML31 and the thirty-second light emitting layer EML32 are blue light emitting layers including a same material, a twenty-first n-type charge generation layer n_CGL21 disposed on the bottom of the thirty-first light emitting component EU31 and a twenty-second n-type charge generation layer n_CGL22 disposed on the bottom of the thirty-second light emitting component EU32 may include a same material. For example, the twenty-first n-type charge generation layer n_CGL21 and the twenty-second n-type charge generation layer n_CGL22 may include an n-type dopant made of at least one of an electron injection material and a metal having a work function in a range of about-4.0 eV to about-1.0 eV. The metal of the twenty-first n-type charge generation layer n_CGL21 and the twenty-second n-type charge generation layer n_CGL22 may include ytterbium (Yb), lithium (Li), and the like.

In accordance with the disclosure, there can be provided a pixel and a display device comprising the same, in which a first injection layer (or electron injection layer) is disposed between a lower electrode (or cathode electrode) and an electron transport component, and a second injection layer (or hole injection layer) is disposed between an upper electrode (or anode electrode) and a hole transport component, so that an injection barrier between the lower electrode and the electron transport component and an injection barrier between the hole transport component and the upper electrode may be lowered, thereby improving light emitting efficiency characteristics.

Also, in accordance with the disclosure, there can be provided a pixel and a display device comprising the same, in which a bank is disposed between a green sub-pixel and a blue sub-pixel, thereby separating a light emitting structure of the green sub-pixel and a light emitting structure of the blue sub-pixel from each other, a p-type charge generation layer in the light emitting structure of the green sub-pixel and a p-type charge generation layer in the light emitting structure of the blue sub-pixel are configured with different materials, thereby improving a charge generation characteristic in the blue sub-pixel, so that light emitting efficiency in each sub-pixel may become uniform, thereby improving reliability.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A pixel comprising:
a first sub-pixel, a second sub-pixel, and a third sub-pixel, which are disposed adjacent to each other, wherein
each of the first, second, and third sub-pixels includes:
a lower electrode;
a pixel defining layer disposed on the lower electrode and expose an area of the lower electrode;
an upper electrode disposed on the pixel defining layer and face the lower electrode; and
a light emitting structure disposed between the lower electrode and the upper electrode,
the pixel further comprises a bank disposed on the pixel defining layer between the second sub-pixel and the third sub-pixel, and
the light emitting structure of the second sub-pixel and the light emitting structure of the third sub-pixel are separated from each other by the bank.

2. The pixel of claim 1, wherein
the first sub-pixel emits light of a first color, the second sub-pixel emits light of a second color different from the first color, and the third sub-pixel emits light of a third color different from the second color, and
the light of the first color is red light, the light of the second color is green light, and the light of the third color is blue light.

3. The pixel of claim 2, wherein
the lower electrode is a cathode electrode, and the upper electrode is an anode electrode,
the light emitting structure includes a first light emitting component which is located on the lower electrode and emits light, a first intermediate layer disposed on the first light emitting component, and a second light emitting component which is located on the first intermediate layer and emits light,
the first light emitting component includes a first electron transport component, a first light emitting layer, and a first hole transport component, which are sequentially stacked on the lower electrode,
the second light emitting component includes a second electron transport component, a second light emitting layer, and a second hole transport component, which are sequentially stacked on the first intermediate layer, and
the first intermediate layer includes a first p-type charge generation layer disposed between the first hole transport component and the second electron transport component and a first n-type charge generation layer disposed between the first p-type charge generation layer and the second electron transport component.

4. The pixel of claim 3, wherein
the light emitting structure of each of the first and second sub-pixels further includes a first injection layer disposed between the lower electrode of the first and second sub-pixels and the first light emitting component and a second injection layer disposed between the second light emitting component and the upper electrode,
the light emitting structure of the third sub-pixel further includes a third injection layer disposed between the lower electrode of the third sub-pixel and the first light emitting component and a fourth injection layer disposed between the second light emitting component and the upper electrode,
the first injection layer and the third injection layer include an electron injection layer, and
the second injection layer and the fourth injection layer include a hole injection layer.

5. The pixel of claim 4, wherein
each of the first and third injection layers includes an n-type dopant having a work function in a range of about −4.0 eV to about −1.0 eV, and
each of the second and fourth injection layers includes a p-type dopant having a Highest Occupied Molecular Orbital (HOMO) in a range of about −9.5 eV to about −1.5 eV.

6. The pixel of claim 5, wherein
the p-type dopant includes at least one of WOₓ, MoOₓ, and VOₓ, and NDP-9, and
x is a rational number between 0 and 3.

7. The pixel of claim 4, wherein
the p-type dopant of the second injection layer and the p-type dopant of the fourth injection layer include different materials,
the p-type dopant of the second injection layer includes NDP-9, and
the p-type dopant of the fourth injection layer includes at least one of an inorganic compound made of a post transition metal and a metalloid, an inorganic compound made of a transition metal and halogen, a post transition metal, and a metalloid.

8. The pixel of claim 4, wherein
the first p-type charge generation layer of each of the first and second sub-pixels and the first p-type charge generation layer of the third sub-pixel include different materials,
the first p-type charge generation layer of each of the first and second sub-pixels includes an NDP-9 p-type dopant, and
the first p-type charge generation layer of the third sub-pixel includes a p-type dopant made of at least one of an inorganic compound made of a post transition metal and a metalloid, an inorganic compound made of a transition metal and halogen, a post transition metal, and a metalloid.

9. The pixel of claim 8, wherein
the post transition metal includes at least one of aluminum (Al), gallium (Ga), indium (In), thallium (Tl), tin (Sn), lead (Pb), flerovium (Fl), bismuth (Bi), and polonium (Po), and
the metalloid includes at least one of boron (B), silicon (Si), germanium (Ge), arsenic (As), antimony (Sb), tellurium (Te), and astatine (At).

10. The pixel of claim 8, wherein
the inorganic compound made of the post transition metal and the metalloid includes at least one of Bi₂Te₃, BiₓTe_{y}, Sb₂Te₃, In₂Te₃, Ga₂Te₃, Al₂Te₃, Tl₂Te₃, As₂Te₃, GeSbTe, SnTe, PbTe, SiTe, GeTe, FlTe, SiGe, AlInSb, AlGaSb, AlAsSb, GaAs, InSb, AlSb, AlAs, AlₓIn (1-x) Sb, AlSb, GaSb, and AlInGaAs,
x is a rational number between 0 and 1, and
y is a rational number between 0 and 2.

11. The pixel of claim 8, wherein
the first and second light emitting layers of each of the first and second sub-pixels include a host of a green phosphorescent layer and a green phosphorescent dopant, and
the first and second light emitting layers of the third sub-pixel include a blue fluorescent host and a blue fluorescent dopant.

12. The pixel of claim 3, wherein
the light emitting structure further includes:
a second intermediate layer disposed on the second light emitting component; and
a third light emitting component located between the second intermediate layer and the upper electrode, the third light emitting component emitting light,
the third light emitting component includes a third electron transport component, a third light emitting layer, and a third hole transport component, which are sequentially stacked between the second intermediate layer and the upper electrode, and
the second intermediate layer includes a second p-type charge generation layer disposed between the second hole transport component and the third electron transport component and a second n-type charge generation layer disposed between the second p-type charge generation layer and the third electron transport component.

13. The pixel of claim 12, wherein
the second p-type charge generation layer of each of the first and second sub-pixels and the first p-type charge generation layer of each of the first and second sub-pixels include a same material, and
the second p-type charge generation layer of the third sub-pixel and the first p-type charge generation layer of the third sub-pixel include a same material.

14. The pixel of claim 13, wherein
the first and second p-type charge generation layers of each of the first and second sub-pixels include an NDP-9 p-type dopant, and
the first and second p-type charge generation layers of the third sub-pixel include a p-type dopant made of at least one of an inorganic compound made of a post transition metal and a metalloid, an inorganic compound made of a transition metal and halogen, a post transition metal, and a metalloid.

15. The pixel of claim 12, wherein one of the first to third light emitting layers of each of the first and second sub-pixels and one of the first to third light emitting layers of the third sub-pixel include a same material.

16. The pixel of claim 15, wherein
the second light emitting layer of each of the first and second sub-pixels and the second light emitting layer of the third sub-pixel include a blue fluorescent host and a blue fluorescent dopant, and
the second p-type charge generation layer of the first sub-pixel, the second p-type charge generation layer of the second sub-pixel, and the second p-type charge generation layer of the third sub-pixel include a same material.

17. The pixel of claim 16, wherein the second p-type charge generation layer of each of the first to third sub-pixels includes a p-type dopant made of at least one of an inorganic compound made of a post transition metal and a metalloid, an inorganic compound made of a transition metal and halogen, a post transition metal, and a metalloid.

18. A pixel comprising:
a first sub-pixel, a second sub-pixel, and a third sub-pixel, which are disposed adjacent to each other, wherein
each of the first, second, and third sub-pixels includes:
a cathode electrode;
a pixel defining layer disposed on the cathode electrode and expose an area of the cathode electrode;
an anode electrode disposed on the pixel defining layer and face the cathode electrode; and
a light emitting structure disposed between the cathode electrode and the anode electrode,
the pixel further comprises a bank disposed on the pixel defining layer between the second sub-pixel and the third sub-pixel,
the light emitting structure includes a first light emitting component which is located on the cathode electrode and emits light, a first intermediate layer disposed on the first light emitting component, a second light emitting component which is located on the first intermediate layer and emits light, a second intermediate layer disposed on the second light emitting component, and a third light emitting component which is located between the second intermediate layer and the anode electrode and emits light,
the first light emitting component includes a first electron transport component, a first light emitting layer, and a first hole transport component, which are sequentially stacked on the cathode electrode,
the second light emitting component includes a second electron transport component, a second light emitting layer, and a second hole transport component, which are sequentially stacked on the first intermediate layer,
the third light emitting component includes a third electron transport component, a third light emitting layer, and a third hole transport component, which are sequentially stacked on the second intermediate layer,
the first intermediate layer includes a first p-type charge generation layer disposed between the first hole transport component and the second electron transport component and a first n-type charge generation layer disposed between the first p-type charge generation layer and the second electron transport component,
the second intermediate layer includes a second p-type charge generation layer disposed between the second hole transport component and the third electron transport component and a second n-type charge generation layer disposed between the second p-type charge generation layer and the third electron transport component,
the second light emitting layer of each of the first and second sub-pixels and the second light emitting layer of the third sub-pixel include a same material and are integrally formed,
the second p-type charge generation layer of each of the first and second sub-pixels and the second p-type charge generation layer of the third sub-pixel include a same material and are integrally formed, and
the first n-type charge generation layer of each of the first and second sub-pixels and the first n-type charge generation layer of the third sub-pixel include a same material and are integrally formed.

19. A display device comprising:
a substrate; and
a first sub-pixel, a second sub-pixel, and a third sub-pixel, which are disposed on the substrate, wherein
each of the first, second, and third sub-pixels includes:
a transistor disposed on the substrate;
a lower electrode disposed on the transistor and electrically connected to the transistor;
a pixel defining layer disposed on the lower electrode and expose an area of the lower electrode;
an upper electrode disposed on the pixel defining layer and face the lower electrode; and
a light emitting structure disposed between the lower electrode and the upper electrode, the light emitting structure including a first injection layer disposed on the lower electrode and a second injection layer disposed on the bottom of the upper electrode,
the display device further comprises a bank disposed on the pixel defining layer between the second sub-pixel and the third sub-pixel,
the light emitting structure of the second sub-pixel and the light emitting structure of the third sub-pixel are separated from each other by the bank, and
the lower electrode is a cathode electrode, and the upper electrode is an anode electrode.

20. The display device of claim 19, wherein
the light emitting structure of the first sub-pixel, the second sub-pixel, and the third sub-pixel further includes a first light emitting component located on the first injection layer, a first intermediate layer disposed on the first light emitting component, a second light emitting component disposed on the first intermediate layer, a second intermediate layer disposed on the second light emitting component, and a third light emitting component disposed on the second intermediate layer,
each of the first to third light emitting components includes an electron transport component, a light emitting layer, and a hole transport component, which are sequentially stacked,
each of the first and second intermediate layers includes a p-type charge generation layer and an n-type charge generation layer disposed on the p-type charge generation layer, and
the p-type charge generation layer of each of the first and second sub-pixels and the p-type charge generation layer of the third sub-pixel include different materials.
